(19) United States
(12) Patent Application Publication
(10) Pub. No.: US 2022/0415733 A1
(43) Pub. Date: Dec. 29, 2022

(54) SEMICONDUCTOR DEVICES AND METHODS OF MANUFACTURING SEMICONDUCTOR DEVICES

(71) Applicant: Amkor Technology Singapore Holding Pte. Ltd., Singapore (SG)

(72) Inventors: Kwang Seok Oh, Incheon (KR); Chang Uk Jang, Incheon (KR); Jin Seok Ryu, Incheon (KR); Seung Jae Yu, Incheon (KR); Weilung Lu, Chandler, AZ (US); Adrian Arcedera, Chandler, AZ (US); Seung Mo Kim, Incheon (KR); Kyung Han Ryu, Incheon (KR); Yi Seul Han, Incheon (KR); Woo Jun Kim, Incheon (KR); Tae Yong Lee, Gyeonggi-do (KR)

(73) Assignee: Amkor Technology Singapore Holding Pte. Ltd., Singapore (SG)

(21) Appl. No.: 17/361,686

(22) Filed: Jun. 29, 2021

(51) Int. Cl. H01L 23/10; H01L 21/52

(52) U.S. Cl. CPC H01L 23/10; H01L 21/52

(57) ABSTRACT

In one example, an electronic device comprises a cavity substrate comprising a substrate base comprising a top side and a bottom side and a cavity wall over the substrate base and defining a cavity, an electronic component over the substrate base and in the cavity, a lid comprising a top side and a bottom side, wherein the lid is over the substrate base and the cavity wall to define an interior of the cavity and an exterior of the cavity, an adhesive between the bottom side of the lid and a top side of the cavity wall, and a vent seal between the interior of the cavity and the exterior of the cavity. Other examples and related methods are also disclosed herein.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, for example resulting in excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIGS. 1A to 1C show a plan view and a cross-sectional view of an example electronic device.

FIGS. 2A to 2G show cross-sectional views of an example method for manufacturing an example electronic device.

FIGS. 3A to 3F show plan views of an example method for manufacturing an example electronic device.

FIGS. 4A and 4B show cross-sectional views of an example electronic device.

FIG. 5 shows a cross-sectional view of an example electronic device.

FIG. 6A shows a plan view of an example electronic device.

FIG. 6B shows a cross-sectional view taken along the line A-A of FIG. 6A.

FIG. 6C shows a cross-sectional view taken along the line B-B of FIG. 6A.

FIG. 7 shows a bottom view illustrating a lid shown in FIG. 6A.

FIG. 8A shows an enlarged view illustrating a region C of FIG. 7.

FIGS. 8B to 8E show bottom views of example venting channels.

FIG. 9A shows a plan view of an example electronic device.

FIG. 9B shows a cross-sectional view taken along the line D-D of FIG. 9A.

FIG. 9C shows a cross-sectional view taken along the line E-E of FIG. 9A.

FIG. 10 shows a bottom view illustrating a lid shown in FIG. 9A.

FIG. 11A shows a cross-sectional view of an example electronic device.

FIG. 11B shows a side view of FIG. 11A taken in a direction F1.

FIG. 11C shows a side view of FIG. 11A taken in a direction F2.

FIG. 12 shows a plan view of a substrate base shown in FIG. 11A.

FIG. 13A shows a cross-sectional view of an example electronic device.

FIG. 13B shows a side view of FIG. 13A taken in a direction G1, and FIG.

FIG. 13C shows a side view of FIG. 13A taken in a direction G2.

FIG. 14 shows a plan view of a substrate base shown in FIG. 13A.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and/or “including,” are “open ended” terms and specify the presence of stated features, but do not preclude the presence or addition of one or more other features. The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements.

### DESCRIPTION

In one example, an electronic device comprises a cavity substrate comprising a substrate base comprising a top side and a bottom side and a cavity wall over the substrate base and defining a cavity, an electronic component over the substrate base and in the cavity, a lid comprising a top side and a bottom side, wherein the lid is over the substrate base and the cavity wall to define an interior of the cavity and an exterior of the cavity, an adhesive between the bottom side of the lid and a top side of the cavity wall, and a vent seal between the interior of the cavity and the exterior of the cavity.

In another example, an electronic device comprises a cavity substrate comprising a substrate base comprising a top side and a bottom side and a cavity wall over the substrate base and defining a cavity, an electronic component over the substrate base and in the cavity, a lid comprising a top side and a bottom side, wherein the lid is over the substrate base and the cavity wall to define an interior of the cavity and an exterior of the cavity, an adhesive between a bottom side of the lid and a top side of the cavity wall, and a venting channel between the interior of the cavity and the exterior of the cavity.

In a further example, a method to manufacture an electronic device, comprises providing a cavity substrate comprising a substrate base having a top side and a bottom side and a cavity wall over the substrate base and defining a cavity, providing an electronic component over the substrate base and in the cavity, providing a lid comprising a top side and a bottom side, wherein the lid is over the substrate base and the cavity wall to define an interior of the cavity and an exterior of the cavity, providing an adhesive between a bottom side of the lid and a top side of the cavity wall, and providing a vent between the interior of the cavity and the exterior of the cavity.

Other examples are included in the present disclosure. Such examples may be found in the figures, in the claims, and/or in the description of the present disclosure.

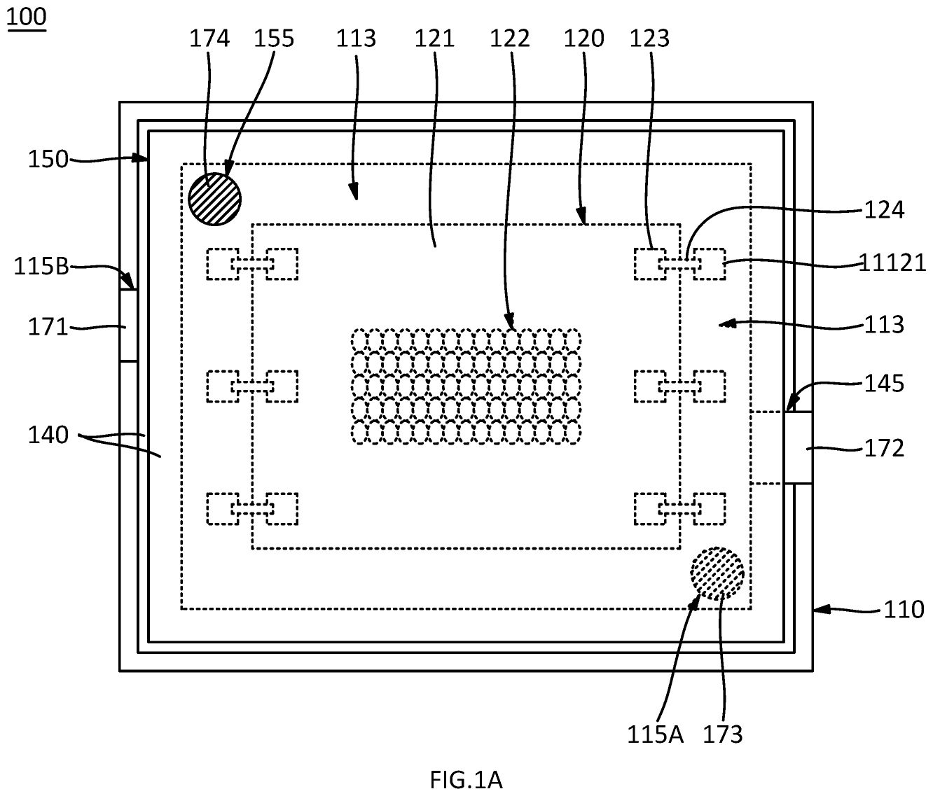

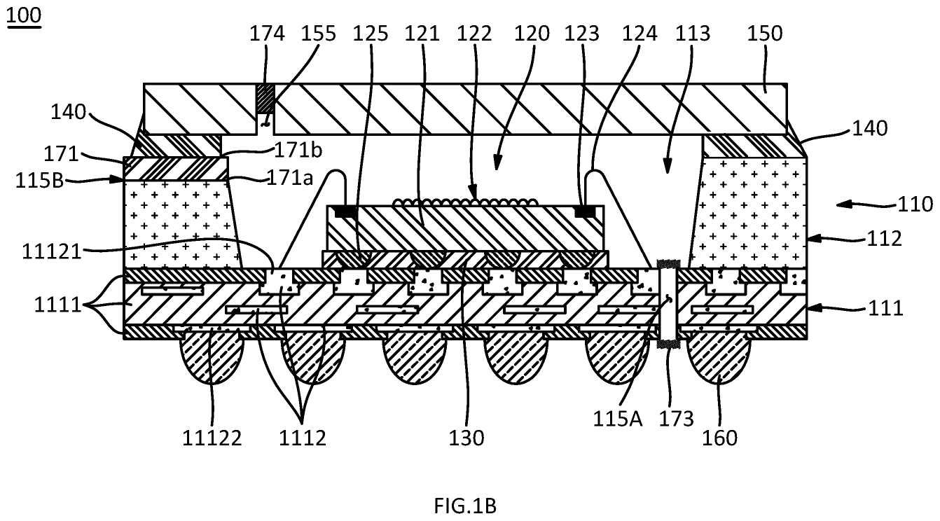

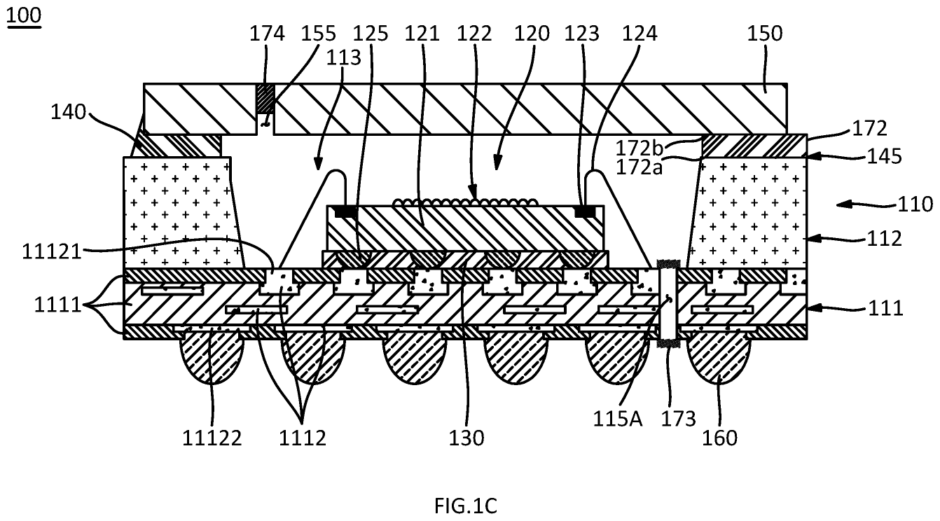

FIGS. 1A, 1B, and 1C show a plan view and cross-sectional views of an example electronic device. In the example shown in FIGS. 1A, 1B, and 1C, electronic device 100 can comprise cavity substrate 110, electronic component 120, underfill 130, adhesive 140, lid 150, external interconnect 160, venting channels 115A, 115B, 145, or 155, and vent seals 171, 172, 173, or 174.

Cavity substrate 110 can comprise substrate base 111, cavity wall 112 over substrate base 111, and cavity 113. In some examples, cavity 113 can be defined by cavity wall 112. Substrate base 111 can comprise a top side and a bottom side, dielectric structure 1111, and conductive structure 1112. Conductive structure 1112 can comprise inward terminals 11121 and outward terminal 11122. Electronic component 120 can comprise component body 121, transceiver 122, and component interconnects 123, 124, or 125. Electronic component 120 can be over substrate base 111 and in cavity 113. Lid 150 can comprise a top side and a bottom side, and can be over substrate base 111 and cavity wall 112 to define an interior of cavity 113 and an exterior of cavity 113. In some examples, adhesive 140 can be between the bottom side of lid 150 and a top side of cavity wall 112. One or more of vent seals 171, 172, 173, or 174 can be between the interior of cavity 113 and the exterior of cavity. Vent seal 171 can contact adhesive 140 and the top side of cavity wall 112. Vent seal 172 can contact the bottom side of lid 150 and the top side of cavity wall 112. In some examples, venting channel 155 can be defined in lid 150 and can extend from the top side of lid 150 to the bottom side of lid 150. Vent seal 174 can be in venting channel 155, vent seal 174 can contact the top side of lid 150 exterior to cavity 113, or vent seal 174 can contact the bottom side of lid 150 interior to cavity 113. In some examples, venting channel 115A can be defined in substrate base 111 and can extend from the top side of substrate base 111 to the bottom side of substrate base 111. Vent seal 173 can be in the venting channel 115A, vent seal 173 can contact the top side of substrate base 111 interior to cavity 113, or vent seal 172 can contact the bottom side of substrate base 111 exterior to cavity 113.

Cavity substrate 110, underfill 130, adhesive 140, lid 150, and external interconnects 160 can be referred to as a semiconductor package or a package, and can provide protection for electronic component 120 from external elements and/or environmental exposure. The semiconductor package can provide electrical coupling between an external component and electronic component 120. In general, electronic device 100 can comprise a vent between the interior of cavity 113 and exterior of cavity 113, and can be configured to relieve a pressure difference between the interior of cavity 113 and the exterior of cavity 113. In some examples, the vent can comprise a venting channel extending vertically or laterally between the interior of cavity 113 and the exterior of cavity 113. In some examples, the vent can comprise a vent seal between the interior of cavity 113 and the exterior of cavity 113.

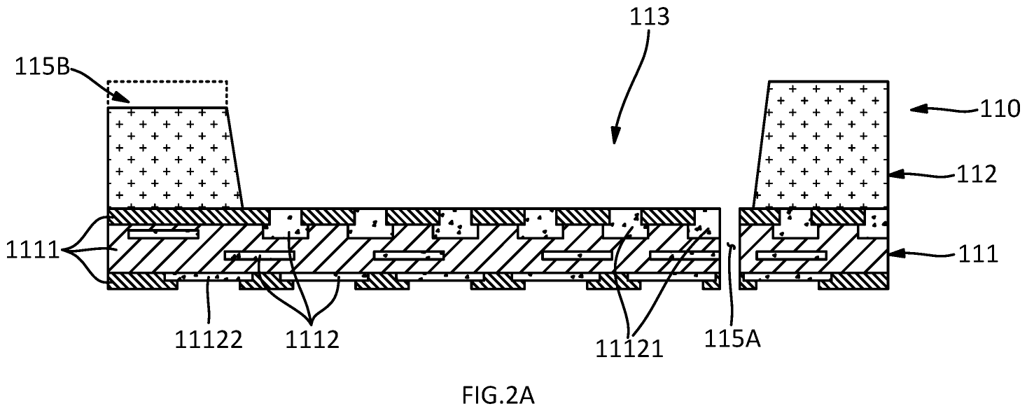

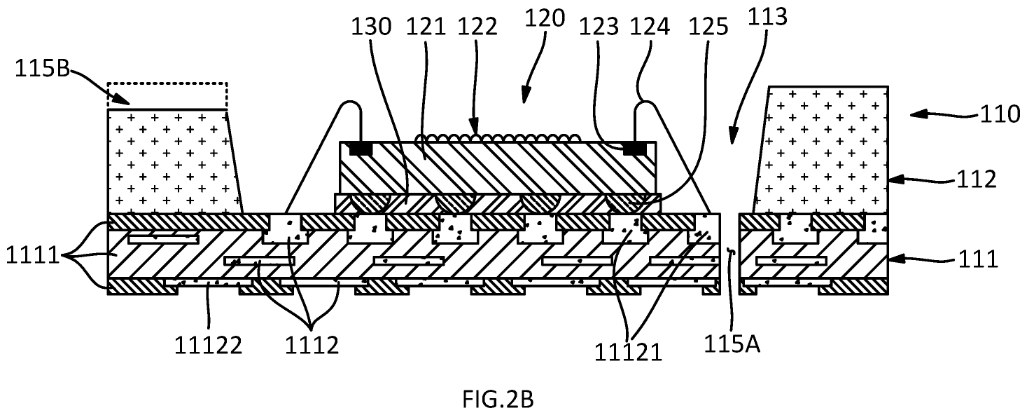

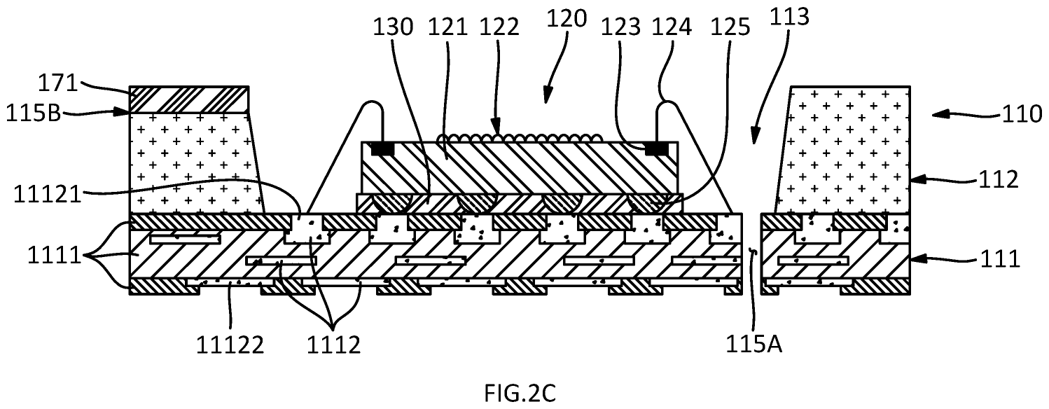

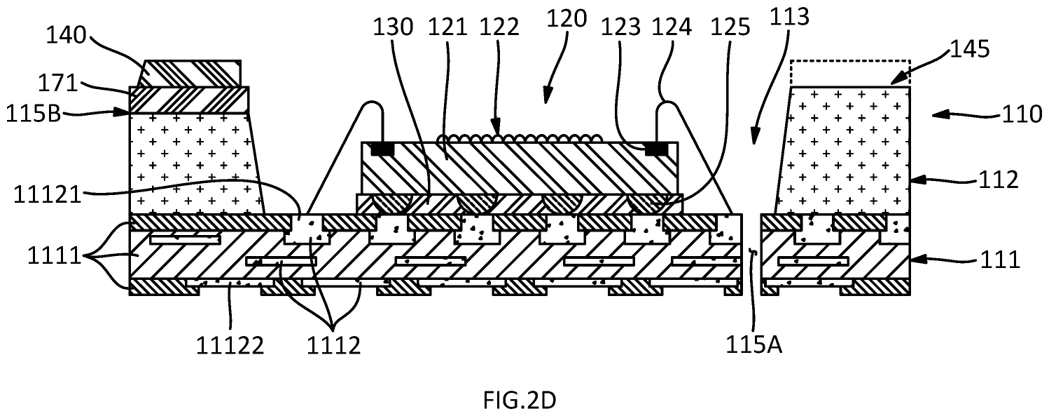

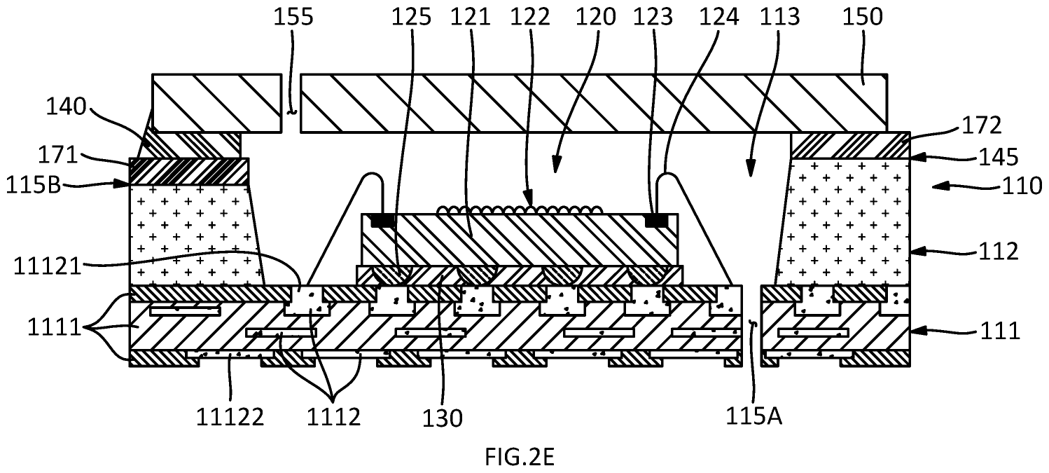

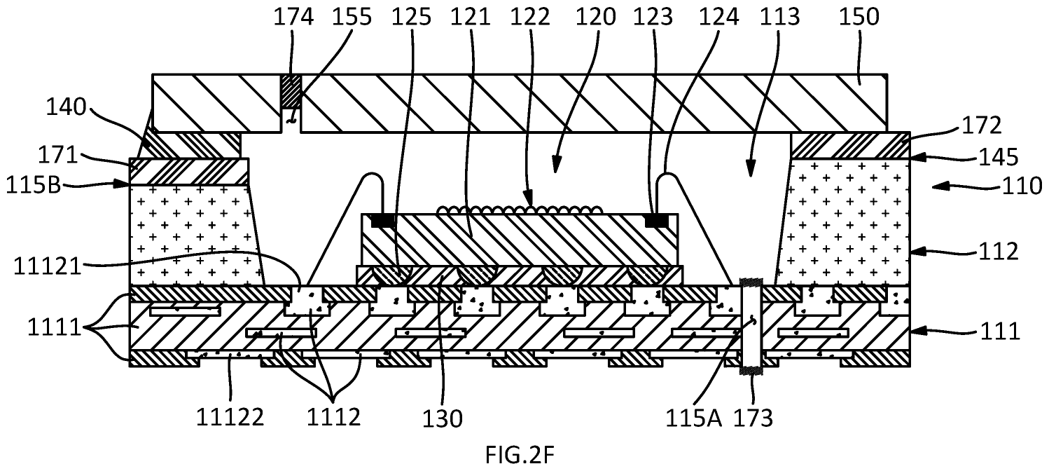

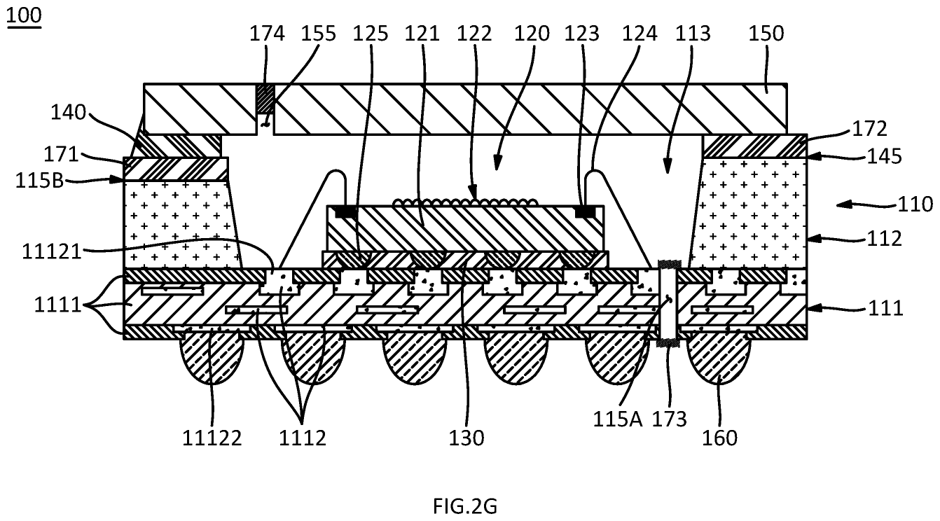

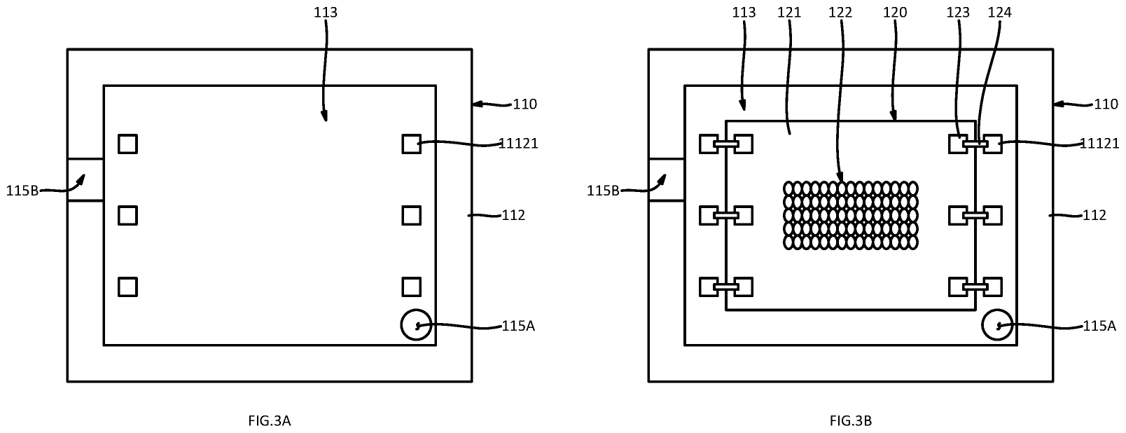

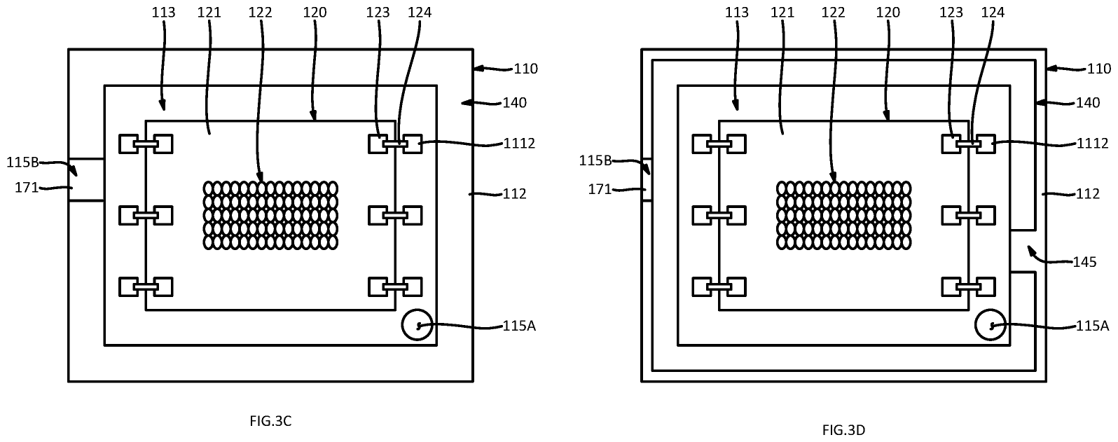

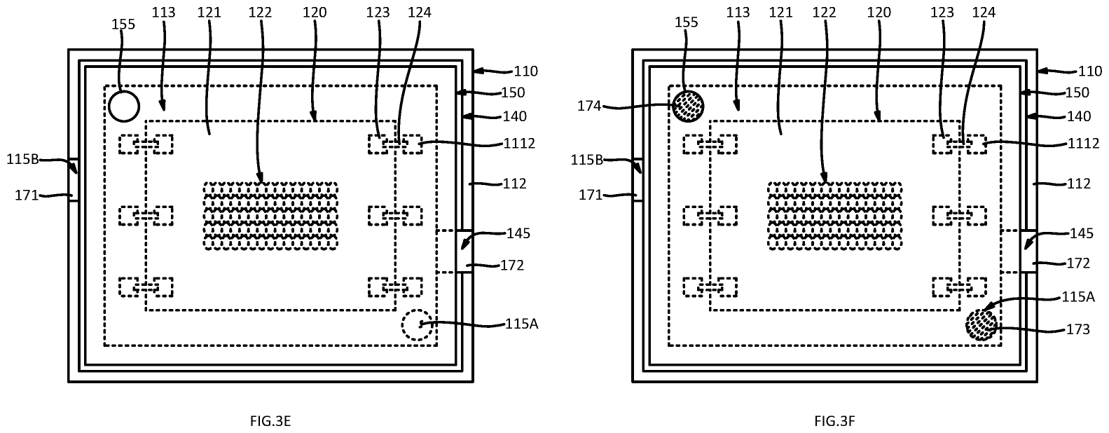

FIGS. 2A to 2G show cross-sectional views of an example method for manufacturing an example electronic device. FIGS. 3A to 3F show plan views of an example method for manufacturing an example electronic device.

FIG. 2A shows a cross-sectional view of electronic device 100 at an initial stage of manufacture, and FIG. 3A shows a plan view of electronic device 100. In the example shown in FIGS. 2A and 3A, cavity substrate 110 can be provided. In some examples, cavity substrate 110 can be provided on a carrier. Cavity substrate 110 can comprise substrate base 111, cavity wall 112, cavity 113, and venting channels 115A and 1158. In some examples, venting channel 1158 can comprise a portion of cavity wall 112 that is lower or shorter over substrate base 111 than another portion of cavity wall 112. In some examples, substrate base 111 can comprise or be referred to as a laminate substrate, a ceramic substrate, or a hybrid substrate. Substrate base 111 can have a thickness in the range from approximately 50 μm to approximately 1500 μm. Substrate base 111 can comprise dielectric structure 1111 and conductive structure 1112.

Dielectric structure 1111 can comprise or be referred to as one or more dielectric layers, solder mask layers, core layers, prepreg layers, mold compound layers, passivation layers, or protection layers. In some examples, dielectric structure 1111 can comprise an electrically insulating material, such as a polymer, polyimide (PI), benzocyclobutene (BCB), polybenzoxazole (PBC)), bismaleimide triazine (BT), a molding material, phenol resin, epoxy, silicone, or acrylate polymer. In some examples, dielectric structure 1111 can be formed using a process, such as spin coating, spray coating, printing, oxidation, physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD). Dielectric structure 1111 can have a thickness in the range from approximately 50 μm to approximately 1500 μm. Dielectric structure 1111 can protect conductive structure 1112 from an external environment. In some examples, dielectric structure 1111 can expose a portion of conductive structure 1112. For example, dielectric structure 1111 can expose inward terminals 11121 and outward terminals 11122.

In some examples, conductive structure 1112 can comprise or be referred to as one or more conductive layers, conductive materials, conductive paths, vias, redistribution layers (RDLs), traces, tracks, or pads. In some examples, conductive structure 1112 can comprise an electrically conductive material, such as copper, aluminum, palladium, titanium, tungsten, titanium/tungsten, nickel, gold, or silver. Conductive structure 1112 can be formed using, for example, sputtering, electroless plating, electroplating, physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD). In some examples, conductive structure 1112 can have a thickness in the range from approximately 5 μm to approximately 50 μm. Conductive structure 1112 can transfer or redistribute signals, current or voltage within substrate base 111. Conductive structure 1112 can comprise inward terminals 11121 and outward terminals 11122.

Inward terminals 11121 can comprise or be referred to as pads, lands, bond pads, under bump metallizations (UBMs), circuit patterns, traces, wiring layers, or metal layers. Inward terminals 11121 can be at a first side (top side) of substrate base 111 or exposed at a top portion of substrate base 111. Inward terminals 11121 can be provided as electrical contacts between substrate base 111 and electronic component 120. In some examples, inward terminals 11121 can be coupled to outward terminals 11122 by one or more conductors or conductive layers through substrate 110. Inward terminals 11121 can comprise an electrically conductive material, such as copper, aluminum, palladium, titanium, tungsten, titanium/tungsten, nickel, gold, or silver. For example, inward terminals 11121 can be formed using a process, such as sputtering, electroless plating, electroplating, physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD). In some examples, inward terminals 11121 can have a thickness in the range from approximately 5 μm to approximately 50 μm.

Outward terminals 11122 can comprise or be referred to as pads, lands, bond pads, under bump metallizations (UBMs), circuit patterns, wiring layers, or metal layers. Outward terminals 11122 can be at a second side (bottom side) of substrate base 111 or exposed at a lower portion of substrate base 111. Outward terminals 11122 can be provided as electrical contacts between substrate base 111 and external interconnects 160. In some examples, outward terminals 11122 can be coupled to inward terminals 11121 by one or more conductors or conductive layers through substrate 110. Outward terminals 11122 can comprise an electrically conductive material, such as copper, aluminum, palladium, titanium, tungsten, titanium/tungsten, nickel, gold, or silver. Outward terminals 11122 can be formed using a process, such as sputtering, electroless plating, electroplating, physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD). In some examples, outward terminals 11122 can have a thickness in the range from approximately 5 μm to approximately 50 μm.

Cavity wall 112 can comprise or be referred to as one or more dielectric layers, mold compound layers, laminate layers, or ceramic layers. In some examples, cavity wall 112 can comprise an electrically insulating material, such as an epoxy molding compound, a polymer, polyimide (PI), benzocyclobutene (BCB), polybenzoxazole (PBO), bismaleimide triazine (BT), a molding material, phenol resin, epoxy, silicone, or acrylate polymer. In some examples, cavity wall 112 can be formed using a process, such as molding, spin coating, spray coating, printing, oxidation, physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD). Cavity wall 112 can be positioned towards an edge of substrate base 111. Referring to FIG. 3A, cavity wall 112 can be a rectangular frame. Cavity wall 112 can extend along edges on the first side of substrate base 111. Cavity wall 112 can be positioned outside venting channel 115A. Cavity wall 112 can be positioned outside inward terminals 11121 coupled to electronic component 120. Cavity wall 112 can expose venting channel 115A and inward terminals 11121. In some examples, cavity wall 112 can enclose electronic component 120 positioned in cavity 113 in one or more lateral directions. Cavity wall 112 can have a greater height than electronic component 120. In some examples, cavity wall 112 can have a height in the range from approximately 100 μm to approximately 2000 μm.

Cavity 113 can be defined or bounded by cavity wall 112. Cavity 113 can be enclosed by cavity wall 112. Cavity 113 can provide a space where electronic component 120 is mounted. Cavity 113 can have a larger area than electronic component 120. In some examples, cavity 113 and cavity wall 112 can be simultaneously provided by forming a dielectric layer over the whole of substrate base 111 and then removing a portion of the dielectric layer. In some examples, cavity 113 and cavity wall 112 can be formed simultaneously, such as by molding with a molding chase.

Venting channel 115A can comprise or be referred to as a lower venting channel. Venting channel 115A can penetrate substrate base 111. Venting channel 115A can comprise a hole extending from the first side to the second side of substrate base 111. In some examples, venting channel 115A can be provided as a channel for venting or leaking compressed air or other gas in cavity 113 in a vertical direction. In some examples, venting channel 115A can be positioned between electronic component 120 and cavity wall 112. In some examples, venting channel 115A can have a diameter in the range from approximately 10 μm to approximately 1000 μm.

Venting channel 1156 can comprise or be referred to as a lateral venting channel. Venting channel 1156 can be defined by a portion of cavity wall 112. In some examples, venting channel 1158 can be a groove extending at the top of cavity wall 112. In some examples, venting channel 1158 can comprise a portion of cavity wall 112 that is lower or shorter over substrate base 111 than another portion of cavity wall 112. In some examples, venting channel 1158 can be a hole laterally penetrating cavity wall 112. Venting channel 115B can be a channel for connecting an interior of cavity wall 112 (or cavity 113) to an exterior side (or an external environment). In some examples, venting channel 1158 can be provided as a channel for venting or leaking compressed air or gas cavity 113 in the lateral or horizontal direction. Venting channel 1158 can be positioned at one side of cavity wall 112. In some examples, venting channel 115B can have a height in the range from approximately 1 μm to approximately 200 μm.

In some examples, substrate 110 can comprise a redistribution layer (“RDL”) substrate. RDL substrates can comprise one or more conductive redistribution layers and one or more dielectric layers that (a) can be formed layer by layer over an electronic device to which the RDL substrate is to be electrically coupled, or (b) can be formed layer by layer over a carrier that can be entirely removed or at least partially removed after the electronic device and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process that can include one or more dielectric layers alternatingly stacked with one or more conductive layers that define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise an electrically conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process, which can include a photolithographic mask through which light is exposed to photo-pattern desired features such as vias in the dielectric layers. The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, that could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in other examples the dielectric materials of the RDL substrates can comprise one or more inorganic dielectric layers. Some examples of inorganic dielectric layer(s) can comprise silicon nitride (Si₃N₄), silicon oxide (SiO₂), and/or SiON. The inorganic dielectric layer(s) can be formed by growing the inorganic dielectric layers using an oxidation or nitridization process instead using photo-defined organic dielectric materials. Such inorganic dielectric layers can be filler-fee, without strands, weaves, or other dissimilar inorganic particles. In some examples, the RDL substrates can omit a permanent core structure or carrier such as, for example, a dielectric material comprising bismaleimide triazine (BT) or FR4 and these types of RDL substrates can be referred to as a coreless substrate. Other substrates in this disclosure can also comprise an RDL substrate.

In some examples, substrate 110 can comprise a pre-formed substrate. The pre-formed substrate can be manufactured prior to attachment to an electronic device and can comprise dielectric layers between respective conductive layers. The conductive layers can comprise copper and can be formed using an electroplating process. The dielectric layers can be relatively thicker non-photo-definable layers that can be attached as a pre-formed film rather than as a liquid and can include a resin with fillers such as strands, weaves, and/or other inorganic particles for rigidity and/or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate which omits the permanent core structure, and the dielectric and conductive layers can be formed on a sacrificial carrier that is removed after formation of the dielectric and conductive layers and before attachment to the electronic device. The pre-formed substrate can be referred to as a printed circuit board (PCB) or a laminate substrate. Such pre-formed substrate can be formed through a semi-additive or modified-semi-additive process. Other substrates in this disclosure can also comprise a pre-formed substrate.

FIG. 2B shows a cross-sectional view of electronic device 100 at a later stage of manufacture, and FIG. 3B shows a plan view of electronic device 100. In the example shown in FIGS. 2B and 3B, electronic component 120 can be provided on substrate base 111 in cavity 113. Electronic component 120 can be coupled to inward terminals 11121 of substrate base 111. In some examples, electronic component 120 can comprise or be referred to as a semiconductor die, a semiconductor chip, a semiconductor device, an electronic device, or a semiconductor package, such as a chip scale package. In some examples, electronic component 120 can comprise or be referred to as a signaling device, a transmitter device, an emitter device, a receiver device, or a sensor device. In some examples, electronic component 120 can comprise or be referred to as an optical device, a laser device, or a vertical-cavity-side-emitting-laser (VCSEL) device. In some examples, electronic component 120 can comprise a radio-frequency (RF) device. In some examples, electronic component 120 can be Wire-Bonded or FlipChip-Bonded. In some examples, electronic component 120 can comprise vias, such as through-silicon-vias (TSV) or through-mold vias (TMV) extending between top and bottom sides of electronic component 120. Electronic component 120 can have a height in the range from approximately 50 μm to approximately 1500 μm. Electronic component 120 can comprise component body 121, transceiver 122, component interconnects 123, and component interconnects 124 and 125.

Component body 121 can comprise, for example, a semiconductor material, such as gallium-arsenide, indium-phosphorus, or silicon. Component body 121 can have a first side and a second side opposite to the first side, for example facing the first side of substrate base 111. Component body 121 can have a thickness in the range from approximately 50 μm to approximately 1000 μm.

Transceiver 122 can be provided on the first side of component body 121. In some examples, transceiver 122 can comprise or be referred to as an emitter or a receiver. In some examples, transceiver 122 can comprise a VCSEL, a lens, a micro-lens array, or an image sensor. Transceiver 122 can be part of transceiver body 121, can be formed on transceiver body 121, or can be coupled to transceiver body 121. In some examples, transceiver 122 can transmit wireless signals, for example optical signals or RF signals, generated from electronic component 120, or can receive external wireless signals. In some examples, transceiver 122 can have a thickness in the range from approximately 50 μm to approximately 1000 μm.

Component interconnects 123 can be located at the first side of component body 121. Component interconnects 123 can be positioned outside transceiver 122. Component interconnects 123 can comprise or be referred to as terminals, pads, lands, bond pads, under bump metallizations (UBMs), circuit patterns, wiring layers, or metal layers. Component interconnects 123 can be electrical contacts for communicating electronic component 120 with substrate base 111. Component interconnects 123 can comprise an electrically conductive material, such as copper, aluminum, palladium, titanium, tungsten, titanium/tungsten, nickel, gold, or silver. In some examples, component interconnects 123 can have a thickness in the range from approximately 0.5 μm to approximately 20 μm.

Component interconnects 124 can couple component interconnects 123 and inward terminals 11121 to each other. In some examples, component interconnects 124 can comprise or be referred to as wires. First ends of component interconnects 124 can be coupled to component interconnects 123, and second ends of component interconnects 124 can be coupled to inward terminals 11121 positioned outside a footprint of electronic component 120. In some examples, component interconnects 124 can comprise an electrically conductive material, such as copper, aluminum, palladium, titanium, tungsten, titanium/tungsten, nickel, gold, or silver.

Component interconnects 125 can be located at the second side of component body 121. In some examples, component interconnects 125 can comprise or be referred as terminals, pads, lands, bond pads, under bump metallizations (UBMs), circuit patterns, wiring layers, metal layers, conductive balls such as solder balls, conductive pillars such as copper pillars, conductive posts having solder caps on copper pillars, and/or conductive bumps. Component interconnects 125 can be coupled to inward terminals 11121. In some examples, component interconnects 125 can be coupled to inward terminals 11121 positioned in a footprint of electronic component 120. Component interconnects 125 can be provided as electrical contacts between electronic component 120 and substrate base 111. In some examples, component interconnects 125 can comprise tin (Sn), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. Component interconnects 125 can be formed by, for example, a ball drop process, a screen-printing process, or an electroplating process.

Optionally, underfill 130 can be provided between substrate base 111 and electronic component 120. Underfill 130 can cover inward terminals 11121 in the footprint of electronic component 120 and component interconnects 125. In some examples, underfill 130 can comprise or referred to as a protective material or a dielectric material. In some examples, underfill 130 can comprise an epoxy, a thermoplastic material, a thermocurable material, polyimide, polyurethane, a polymeric material, a filled epoxy, a filled thermoplastic material, a filled thermocurable material, a filled polyimide, a filled polyurethane, a filled polymeric material or a fluxed underfill. Underfill 130 can have a height in the range from approximately 5 μm to approximately 500 μm.

FIG. 2C shows a cross-sectional view of electronic device 100 at a later stage of manufacture, and FIG. 3C shows a plan view of electronic device 100. In the example shown in FIGS. 2C and 3C, vent seal 171 can be provided at venting channel 115B. In some examples, vent seal 171 can comprise or be referred to as a lateral vent seal. Vent seal 171 can seal venting channel 1156. In some examples, vent seal 171 can be formed on venting channel 1156 provided on cavity wall 112 and can seal cavity 113 from an external environment. In some examples, vent seal 171 can prevent moisture or dust from being induced into cavity 113. In some examples, vent seal 171 can be hydrophobic or can prevent passage of moisture.

In some examples, vent seal 171 can comprise or be referred to as an impermeable vent seal. Vent seal 171 can comprise, for example, a flexible material, such as silicone. Impermeable vent seal 171 can be impermeable to air or gas, but when there is sufficient pressure imbalance between the interior and exterior of cavity 113, impermeable vent seal 171 can vent or leak the air or gas to relieve pressure.

In some examples, when there is sufficient pressure imbalance between the interior and exterior of cavity 113, the pressure can generate a venting or leaking gap at the interface 171a (FIG. 1B) between impermeable vent seal 171 and venting channel 115B such that the compressed air or gas can be vented or leaked through such gap. For example, when there is a pressure imbalance between the interior and exterior of cavity 113, the pressure can generate a venting or leaking gap at interface 171a (FIG. 1B) between impermeable vent seal 171 and cavity wall 112, or at interface 171b (FIG. 1B) between impermeable vent seal 171 and adhesive 140. In some examples, when the pressure is sufficiently balanced by the venting or leaking, impermeable vent seal 171 can seal the venting or leaking gap.

In some examples, vent seal 171 can comprise or be referred to as a permeable vent seal, a breathable vent seal, or a porous vent seal. Permeable vent seal 171 can comprise, for example, a membrane or mesh of expanded polytetrafluorethylene (ePTFE) material stands. Permeable vent seal 171 can be at least partially permeable to air or gas. In some examples, when there is a pressure imbalance between the interior and exterior of cavity 113, the compressed air or gas in cavity 113 can be vented or leaked through permeable vent seal 171.

FIG. 2D shows a cross-sectional view of electronic device 100 at a later stage of manufacture, and FIG. 3D shows a plan view of electronic device 100. In the example shown in FIGS. 2D and 3D, adhesive 140 can be provided on cavity wall 112. Adhesive 140 can also be provided on vent seal 171 on venting channel 115B. In some examples, adhesive 140 can comprise or be referred to as an adhesive film or an adhesive tape. Adhesive 140 can be configured to secure lid 150 to an upper side of cavity substrate 110. In some examples, adhesive 140 can comprise venting channel 145.

Venting channel 145 can comprise or be referred to as lateral venting channel. Venting channel 145 can extend through adhesive 140. In some examples, venting channel 145 can be a hole penetrating adhesive 140 in the lateral or horizontal direction and a vertical direction. Venting channel 145 can expose a portion of cavity wall 112. In some examples, venting channel 145 can be formed by providing adhesive 140 over the whole of cavity wall 112 and removing a portion of adhesive 140. In some examples, venting channel 145 can be formed by providing adhesive 140 over cavity wall 112, except over a portion where venting channel 145 is defined. Venting channel 145 can be configured to relieve a pressure difference between the interior and exterior of cavity 113. In some examples, venting channel 145 can be provided as channel for venting or leaking the compressed air or gas in cavity 113 in the lateral or horizontal direction. Venting channel 145 can be spaced apart from venting channel 1156 of cavity wall 112. In some examples, venting channel 145 can be positioned opposite to venting channel 115B of cavity wall 112. In some examples, venting channel 145 can have a width in the range from approximately 1 μm to approximately 500 μm.

FIG. 2E shows a cross-sectional view of electronic device 100 at a later stage of manufacture, and FIG. 3E shows a plan view of electronic device 100. In the example shown in FIGS. 2E and 3E, vent seal 172 can be provided on venting channel 145, and lid 150 can be coupled over cavity wall 112. In some examples, vent seal 172 can comprise or be referred to as a lateral vent seal. Vent seal 172 can seal venting channel 145. In some examples, vent seal 172 can be provided on venting channel 145 provided on adhesive 140 and can cut off cavity 113 from an external environment. In some examples, vent seal 172 can prevent moisture or dust from being induced into cavity 113. In some examples, vent seal 172 can be hydrophobic or can prevent passage of moisture.

In some examples, vent seal 172 can comprise or be referred to as an impermeable vent seal. Vent seal 172 can comprise, for example, a flexible material such as silicone. Impermeable vent seal 172 can be impermeable to air or gas, but when there is sufficient pressure imbalance between the interior and exterior of cavity 113, impermeable vent seal 172 can vent or leak the air or gas to relieve pressure. In some examples, when there is a pressure imbalance between the interior and exterior of cavity 113, the pressure can generate a venting or leaking gap at the interface 172a (FIG. 1C) between impermeable vent seal 172 and venting channel 145, or at the interface 172b (FIG. 1C) between impermeable vent seal 172 and lid 150, such that the compressed air or gas can be vented or leaked through such gap. In some examples, when the pressure is sufficiently balanced by the venting or leaking, impermeable vent seal 172 can seal the venting or leaking gap.

In some examples, vent seal 172 can comprise or be referred to as a permeable vent seal, a breathable vent seal, or a porous vent seal. For example, permeable vent seal 172 can comprise a membrane or mesh of expanded polytetrafluorethylene (ePTFE) material stands. Permeable vent seal 172 can be permeable to air or gas. In some examples, when there is a pressure imbalance between the interior and exterior of cavity 113, the compressed air or gas in cavity 113 can be vented or leaked through permeable vent seal 172.

In the example shown in FIGS. 2E and 3E, lid 150 can be provided on cavity substrate 110. Lid 150 can be attached to a top of cavity substrate 110 through adhesive 140. Lid 150 can cover a top portion of vent seal 172 provided on venting channel 145 of adhesive 140. In some examples, lid 150 can comprise or be referred to as a cover. Lid 150 can cover cavity 113 of cavity substrate 110. In some examples, lid 150 can have a larger width than cavity 113, and thus can be positioned on cavity wall 112. Lid 150 can be translucent to permit passage of wireless signals, for example optical signals, RF signals, and so on. In some examples, lid 150 can comprise glass. In some examples, lid 150 can be permeable to an optical signal generated from electronic component 120 or an optical signal generated from an external component. Lid 150 can have a thickness in the range from approximately 200 μm to approximately 1200 μm.

In some examples, lid 150 can comprise venting channel 155. Venting channel 155 can comprise or be referred to as an upper venting channel. Venting channel 155 can penetrate lid 150. Venting channel 155 can be a hole extending from a top to a bottom side lid 150. In some examples, venting channel 155 can be provided as a channel for venting or leaking the compressed air or gas in cavity 113 in a vertical direction. In some examples venting channel 155 can be positioned at a corner of lid 150. In some examples, venting channel 155 can have a diameter in the range from approximately 10 μm to approximately 1000 μm.

FIG. 2F shows a cross-sectional view of electronic device 100 at a later stage of manufacture, and FIG. 3F shows a plan view of electronic device 100. In the example shown in FIGS. 2F and 3F, vent seal 173 can be provided at venting channel 115A, or vent seal 174 can be provided at venting channel 155. In some examples, vent seals 173 and 174 can prevent moisture or dust from being induced into cavity 113. In some examples, vent seals 173 and 174 can be hydrophobic or can prevent passage of moisture.

In some examples, vent seal 173 can comprise or be referred to as a lower vent seal. Vent seal 173 can seal venting channel 115A. In some examples, vent seal 173 can be provided on venting channel 115A of substrate base 111 and seal off cavity 113 from an external environment. In some examples, vent seal 173 can be coupled to venting channel 115A from the second side (bottom side) of substrate base 111 to then seal a bottom end of venting channel 115A. In some examples, vent seal 173 can be provided at a top end of venting channel 115A.

Vent seal 174 can comprise or be referred to as an upper vent seal. Vent seal 174 can seal venting channel 155. In some examples, vent seal 174 can be provided on venting channel 155 of lid 150 and can seal off cavity 113 from an external environment. In some examples, vent seal 174 can be coupled to venting channel 155 from a top side of lid 150 to then seal a top end of venting channel 155. In some examples, venting seal 174 can be provided at a bottom end of vent channel 155.

In some examples, vent seals 173 or 174 can comprise or be referred to as impermeable vent seals. Vent seals 173 or 174 can comprise, for example, a flexible material, such as silicone.

Impermeable vent seals 173 or 174 can be impermeable to air or gas, but when there is sufficient pressure imbalance between the interior and exterior of cavity 113, impermeable vent seals 173 or 174 can vent or leak the air or gas to relieve pressure.

In some examples, when there is sufficient pressure imbalance between the interior and exterior of cavity 113, the pressure can generate a venting or leaking gap at the interface between impermeable vent seal 173 and venting channel 115A, such that the compressed air or gas can be vented or leaked through such gap. In some examples, when the pressure is sufficiently balanced by the venting or leaking, impermeable vent seal 173 can seal the venting or leaking gap.

In some examples, when there is sufficient pressure imbalance between the interior and exterior of cavity 113, the pressure can generate a venting or leaking gap at the interface between impermeable vent seal 174 and venting channel 155, such that the compressed air or gas can be vented or leaked through such gap. In some examples, when the pressure is sufficiently balanced by the venting or leaking, impermeable vent seal 174 can seal the venting or leaking gap.

In some examples, vent seals 173 or 174 can comprise or be referred to as permeable vent seals, breathable vent seals, or porous vent seals. Permeable vent seals 173 and 174 can comprise, for example, a membrane or mesh of expanded polytetrafluorethylene (ePTFE) material stands. Permeable vent seals 173 and 174 can be permeable to air or gas. In some examples, when there is a pressure imbalance between the interior and exterior of cavity 113, the compressed air or gas in cavity 113 can be vented or leaked through permeable vent seals 173 and 174.

FIG. 2G shows a cross-sectional view of electronic device 100 at a later stage of manufacture. In the example shown in FIG. 2G, external interconnects 160 can be provided on the second side (bottom side) of substrate base 111. External interconnects 160 can be coupled to outward terminals 11122 of substrate base 111. In some examples, external interconnects 160 can comprise or be referred to as conductive bumps, balls, pillars or posts. External interconnects 160 can comprise tin (Sn), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, or Sn—Ag—Cu. External interconnects 160 can be formed by, for example, a ball drop process, a screen-printing process, or an electroplating process. External interconnects 160 can have a height in the range from approximately 50 μm to approximately 1000 μm. External interconnects 160 can be provided as coupling channels between electronic device 100 and an external component.

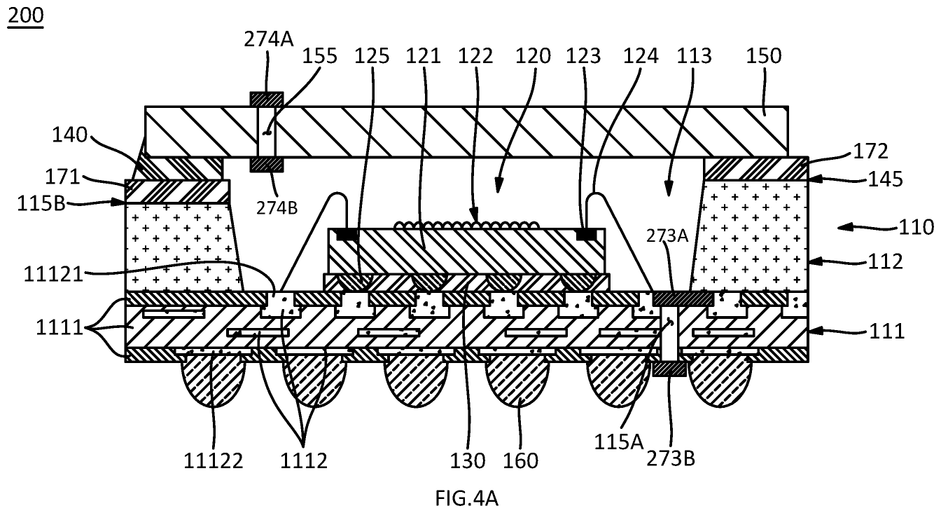

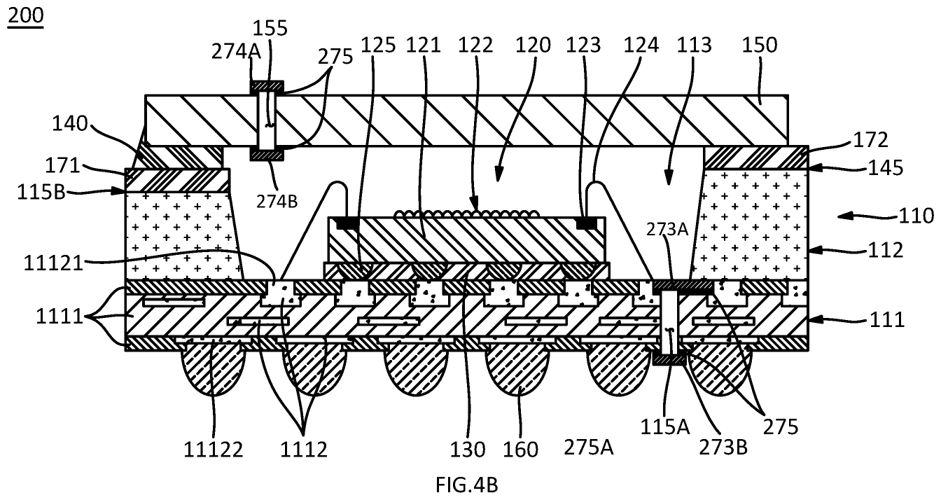

FIGS. 4A and 4B show cross-sectional views of an example electronic device. In the example shown in FIG. 4A, electronic device 200 can comprise cavity substrate 110, electronic component 120, underfill 130, adhesive 140, lid 150, external interconnects 160, venting channels 115A, 115B, 145, or 155, and vent seals 171, 172, 273A, 273B, 274A, or 274B. In some examples, electronic device 200 can comprise corresponding elements, features, materials, or formation processes similar to those of electronic device 100 or other electronic devices described here.

In some examples, vent seals 273A or 273B can comprise corresponding elements, features, materials, or formation processes similar to those of vent seal 173 previously described. Vent seals 273A or 273B can comprise or be referred to as lower vent seals. Vent seals 273A or 273B can seal venting channel 115A. Vent seal 273A can be provided towards a top of venting channel 115A, or vent seal 273B can be provided towards a bottom of venting channel 115A. In some examples, vent seal 273A can cover venting channel 115A over the first side (top side) of substrate base 111, or vent seal 273B can cover venting channel 115A under the second side (bottom side) of substrate base 111. In some examples, vent seal 273A can be partially covered by cavity wall 112. In some examples, when vent seal 273A exists over venting channel 115A, vent seal 273B existing under venting channel 115A can be omitted. Conversely, when vent seal 273B exists under venting channel 115A, vent seal 273A existing over venting channel 115A can be omitted.

In some examples, vent seals 274A, 274B can comprise corresponding elements, features, materials, or formation processes similar to those of vent seal 174 previously described. Vent seals 274A, 274B can comprise or be referred to as upper vent seals. Vent seals 274A, 274B can seal venting channel 155. Vent seal 274A can be provided over venting channel 155, or vent seal 274B can be provided under venting channel 155. In some examples, vent seal 274A can cover venting channel 155 over the top side of lid 150, and vent seal 274B can cover venting channel 155 under the bottom side of lid 150. In some examples, when vent seal 274A exists over venting channel 155, vent seal 274B existing under venting channel 155 can be omitted. Conversely, when vent seal 274B exists under venting channel 115A, vent seal 274A existing over venting channel 155 can be omitted.

In some examples, vent seals 273A, 273B, 274A, or 274B can comprise or be referred to as permeable vent seals, breathable vent seals, or porous vent seals. Permeable vent seals 273A, 273B, 274A, or 274B can comprise, for example, a membrane or mesh of expanded polytetrafluorethylene (ePTFE) material stands. Permeable vent seals 273A, 273B, 274A, or 274B can be permeable to air or gas. In some examples, when there is a pressure imbalance between the interior and exterior of cavity 113, the compressed air or gas in cavity 113 can be vented or leaked through permeable vent seals 273A, 273B, 274A, or 274B.

In the example shown in FIG. 4B, vent seals 273A, 273B, 274A, 274B can comprise carrier film 275. FIG. 4B can be a more detailed view of FIG. 4A to illustrate carrier film 275. Carrier film 275 can comprise or be referred to as an adhesive film or an adhesive tape. Carrier film 275 can attach vent seals 273A, 273B, 274A, or 274B to substrate base 111 or lid 150, respectively. In some examples, carrier film 275 can be at one side of each of vent seals 273A, 273B, 274A, or 274B, and can be positioned at edges of vent seals 273A, 273B, 274A, or 274B. Carrier film 275 can be impermeable, but can comprise one or more apertures aligned with venting channels 115A, 155. The one or more apertures of carrier film 275 can be provided as paths through where the compressed air or gas in cavity 113 is vented or leaked.

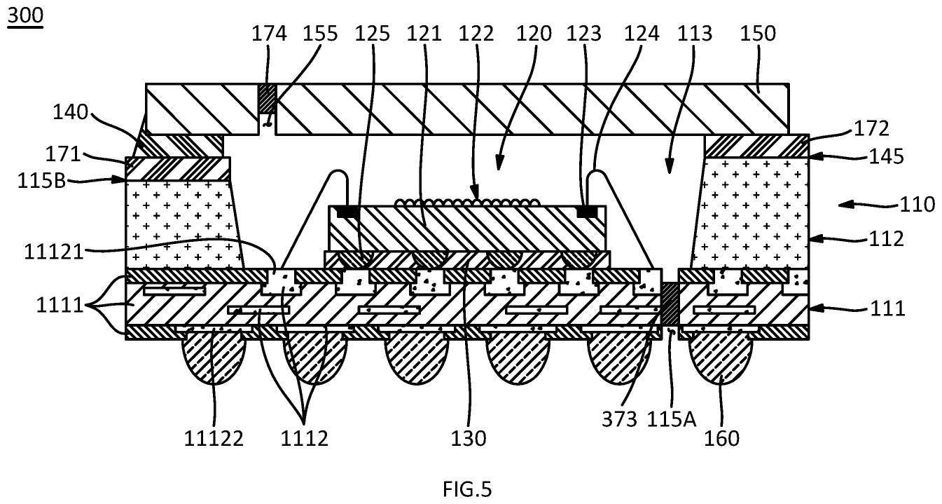

FIG. 5 shows a cross-sectional view of an example electronic device. In the example shown in FIG. 5, electronic device 300 can comprise cavity substrate 110, electronic component 120, underfill 130, adhesive 140, lid 150, external interconnects 160, venting channels 115A, 115B, 145, or 155, and vent seals 171, 172, 373, 174. In some examples, electronic device 300 can comprise corresponding elements, features, materials, or formation processes similar to those of electronic device 100, 200, or other electronic devices described here.

In some examples, vent seal 373 can comprise corresponding elements, features, materials, or formation processes similar to those of vent seal 173 previously described. Vent seal 373 can comprise or be referred to as a lower vent seal or an embedded vent seal. Vent seal 373 can be part of substrate base 111, and can be embedded in venting channel 115A of substrate base 111 defined by one or more layers of dielectric structure 1111. In some examples, a top side or a bottom side of vent seal 373 can be partially sunk relative to the corresponding top or bottom of substrate base 111. In some examples, vent seal 373 can be provided at a middle portion of venting channel 115A. The top side of vent seal 373 can be lower than the first side (top side) of substrate base 111. The bottom side of vent seal 373 can be higher than the second side (bottom side) of substrate base 111.

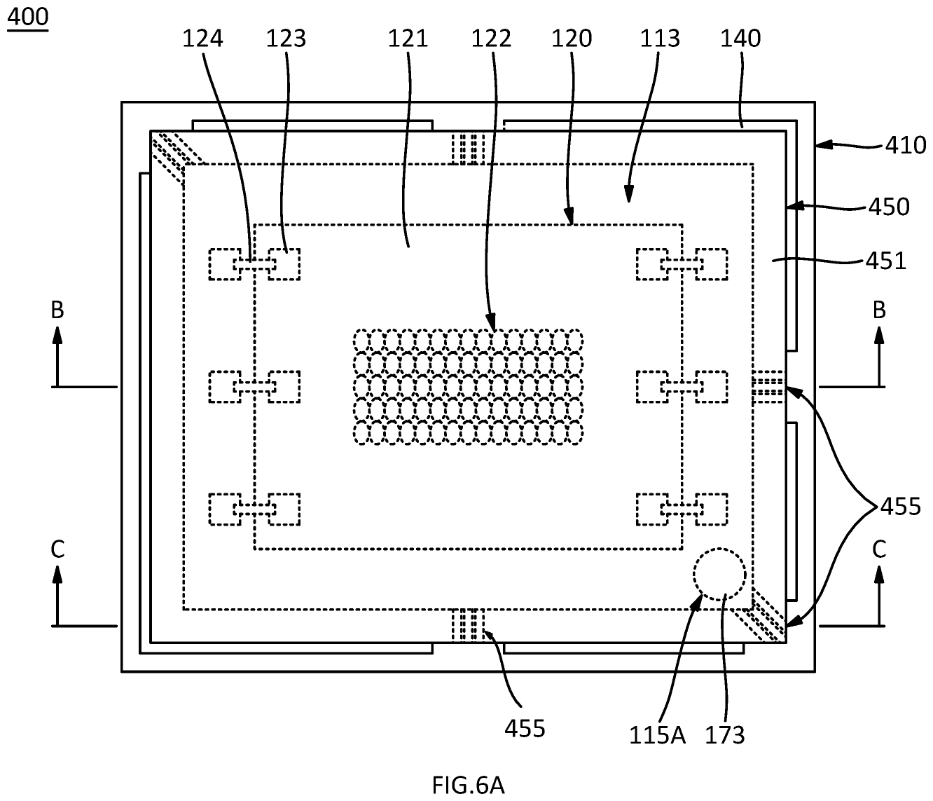

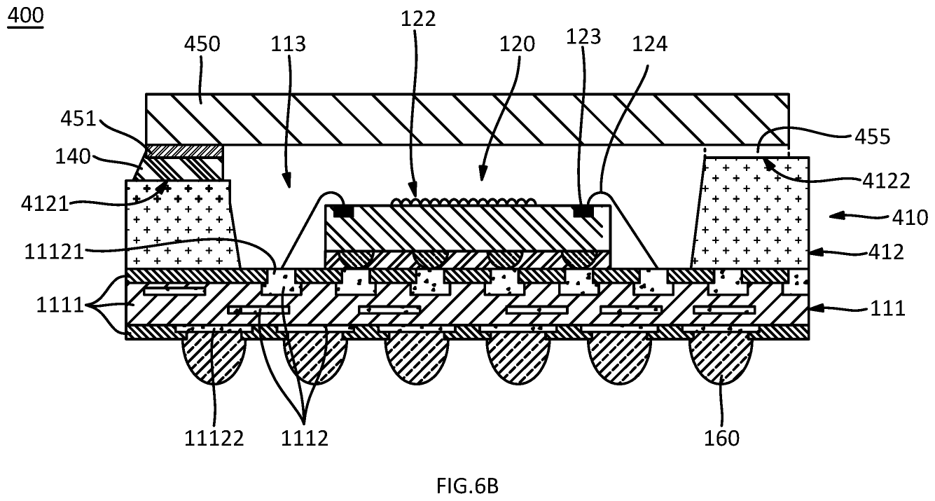

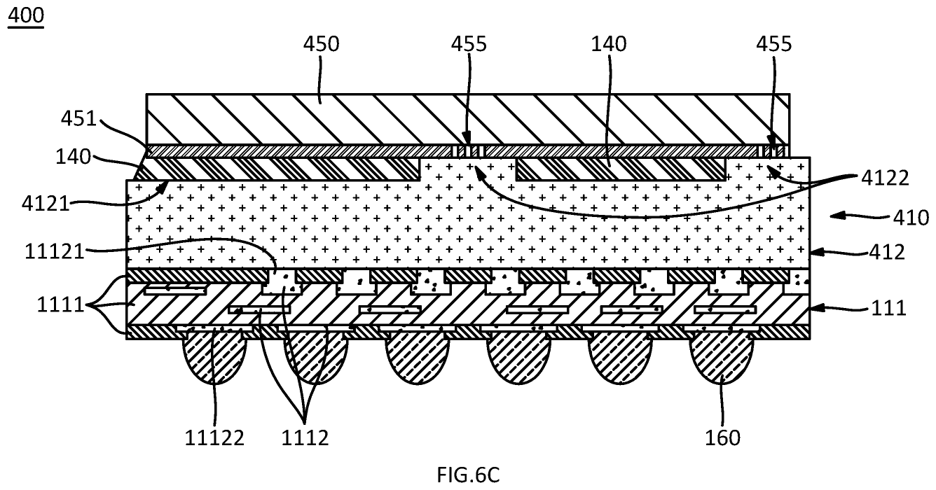

FIG. 6A shows a plan view of an example electronic device. FIG. 6B shows a cross-sectional view taken along the line B-B of FIG. 6A, and FIG. 6C shows a cross-sectional view taken along the line C-C of FIG. 6A. In the example shown in FIGS. 6A to 6C, electronic device 400 can comprise cavity substrate 410, electronic component 120, adhesive 140, lid 450, external interconnects 160, venting channels 115A and 455, and vent seal 173.

Cavity substrate 410 can comprise substrate base 111, cavity wall 412, and cavity 113. In some examples, cavity wall 412 can comprise corresponding elements, features, materials, or formation processes similar to those of cavity wall 112. Cavity wall 412 can comprise wall ledge 4121 and wall steps 4122.

Wall ledge 4121 can be shorter or can have a lower height than wall steps 4122. Wall ledge 4121 can be sunk relative to wall steps 4122, or wall steps 4122 can protrude from wall ledge 4121. Wall ledge 4121 can provide space where adhesive 140 can be located. A top side of wall ledge 4121 can be covered by adhesive 140. Adhesive 140 can couple wall ledge 4121 and lid 450 together. Wall steps 4122 can upwardly protrude from wall ledge 4121. Wall steps 4122 can comprise multiple wall steps on cavity wall 412 so as to be spaced apart from each other. In some examples, wall steps 4122 can be provided at corners of cavity wall 412 or on at least one side of cavity wall 412. Top sides of wall steps 4122 can be exposed without being covered by adhesive 140. Wall steps 4122 can contact lid 450. In some examples, wall steps 4122 and venting channels 455 of lid 450 can contact each other. In some examples, venting channels 455 can be in trench layer 451 over one or more of wall steps 4122. In general, any of the venting channels described herein can comprise a pathway between the interior of cavity 113 and the exterior of cavity.

In some examples, lid 450 can comprise corresponding elements, features, materials, or formation processes similar to those of lid 150. Lid 450 can comprise trench layer 451 and venting channels 455. Trench layer 451 can be provided on or contact a bottom side of lid 450 and can be adjacent to a top side of cavity wall 112. Trench layer 451 can be provided along the periphery of lid 450. In some examples, trench layer 451 can comprise a photosensitive material or polyimide (PI). Trench layer 451 can be attached to cavity wall 412 through adhesive 140. In some examples, trench layer 451 can be attached to wall ledge 4121 through adhesive 140, and adhesive 140 can contact the bottom side of trench layer 451. In some examples, trench layer 451 can contact wall steps 4122. Trench layer 451 can comprise venting channels 455, for example where venting channels 455 are in trench layer 451. In some examples, trench layer 451 can have a thickness in the range from approximately 0.5 μm to approximately 5 μm.

Venting channels 455 can comprise or be referred to as lateral venting channels. Venting channels 455 can be located to correspond to the location of wall steps 4122. Venting channels 455 can comprise one or more trenches or holes laterally extending across trench layer 451. Venting channels 455 can be one or more trenches or holes vertically penetrating trench layer 451. Venting channels 455 can extend between the bottom side of lid 450 and the top sides of wall steps 4122. In some examples, venting channels 455 can be channels for communicating cavity 113 with an external environment. The trenches constituting venting channels 455 can be relatively narrow in width, and thus can prevent moisture or dust from being induced into cavity 113. In some examples, the trenches can have a width of about 5 μm or less. In some examples, when there is a pressure imbalance between the interior and exterior of cavity 113, the compressed air or gas in cavity 113 can be vented or leaked through venting channels 455.

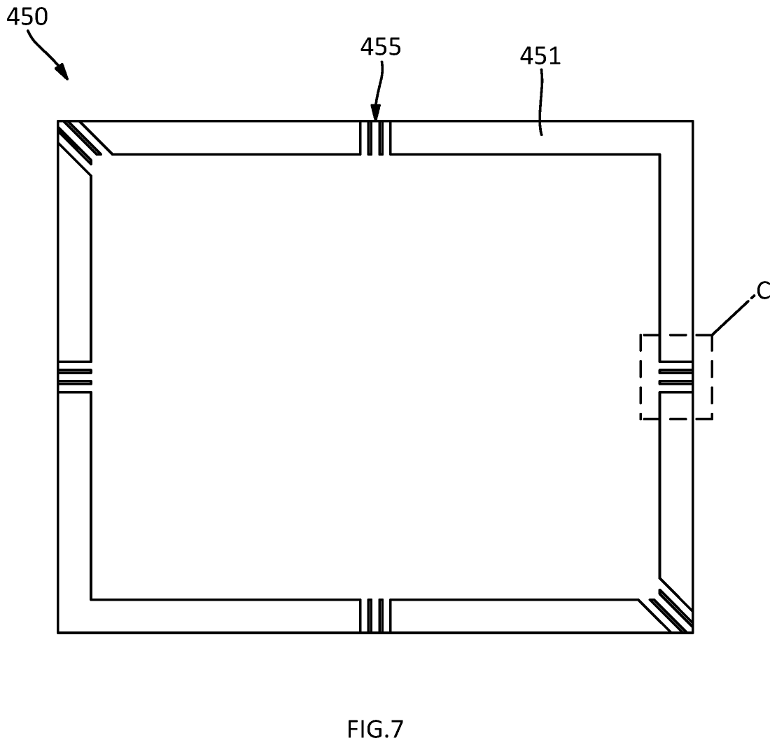

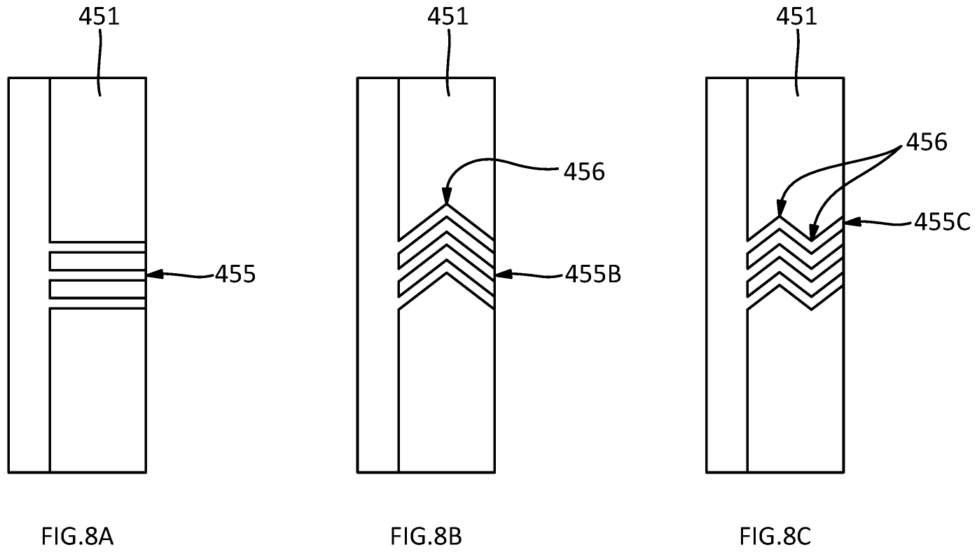

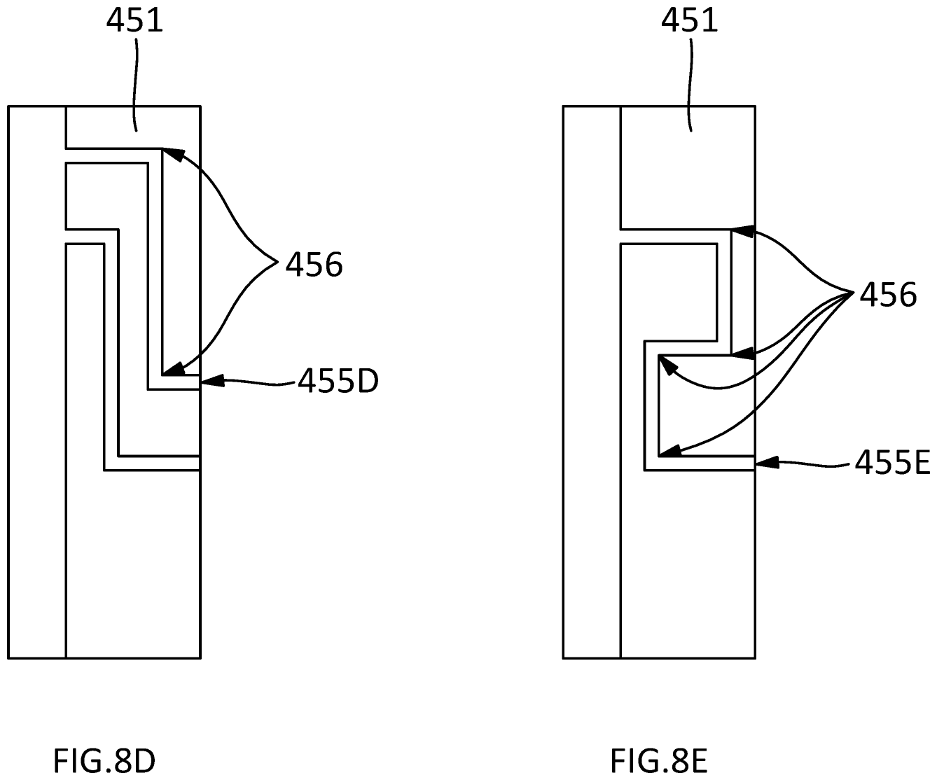

FIG. 7 shows a bottom view illustrating lid 450 shown in FIG. 6A. FIG. 8A shows an enlarged view illustrating venting channels at region C of FIG. 7, and FIGS. 8B to 8E show bottom views of alternative venting channels. Referring to FIGS. 7 and 8A, venting channels 455 can comprise one or more trenches or holes across or through trench layer 451. The one or more trenches or holes can have linear or arcuate patterns. Referring to FIGS. 8B to 8E, venting channels 455B, 455C, 455D, or 455E can be patterns having at least one bend portion 456.

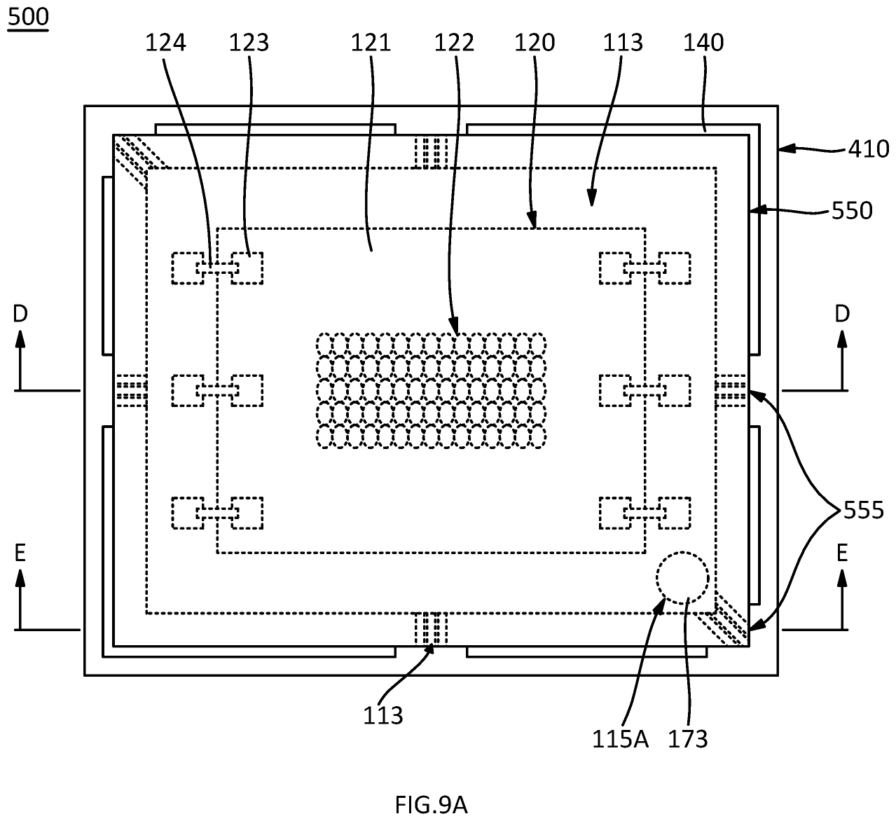

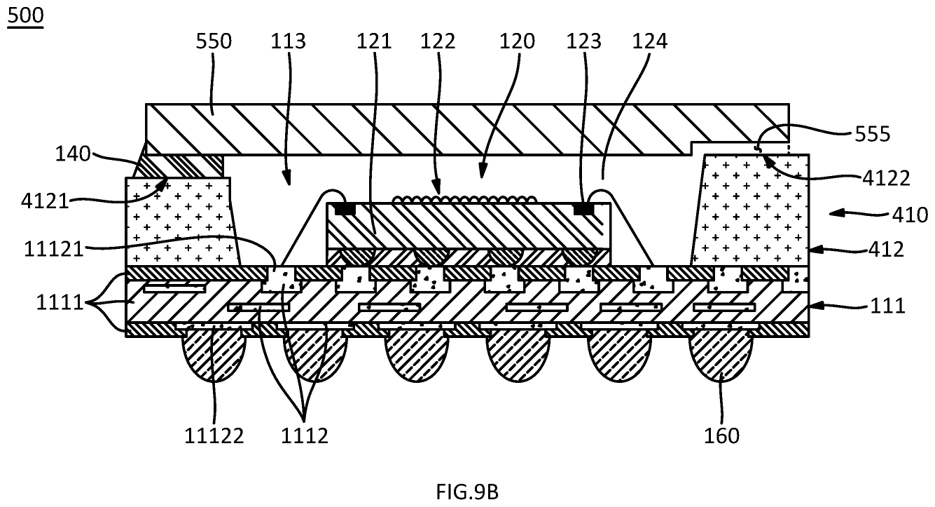

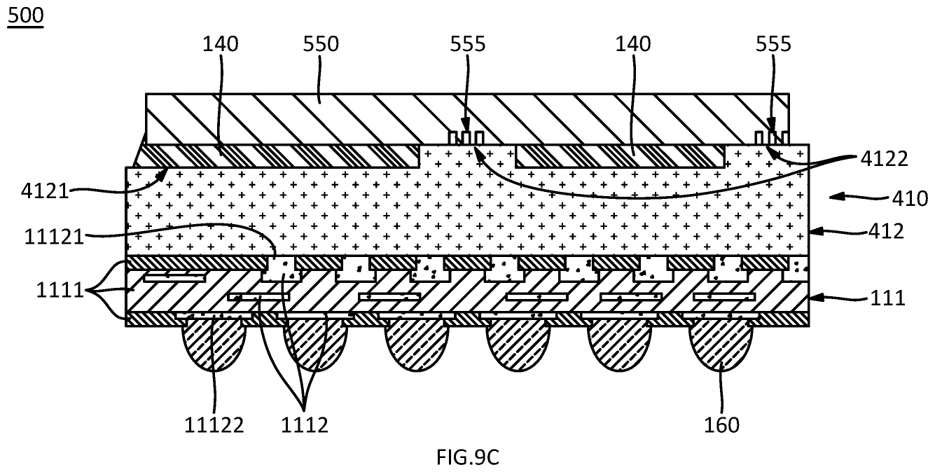

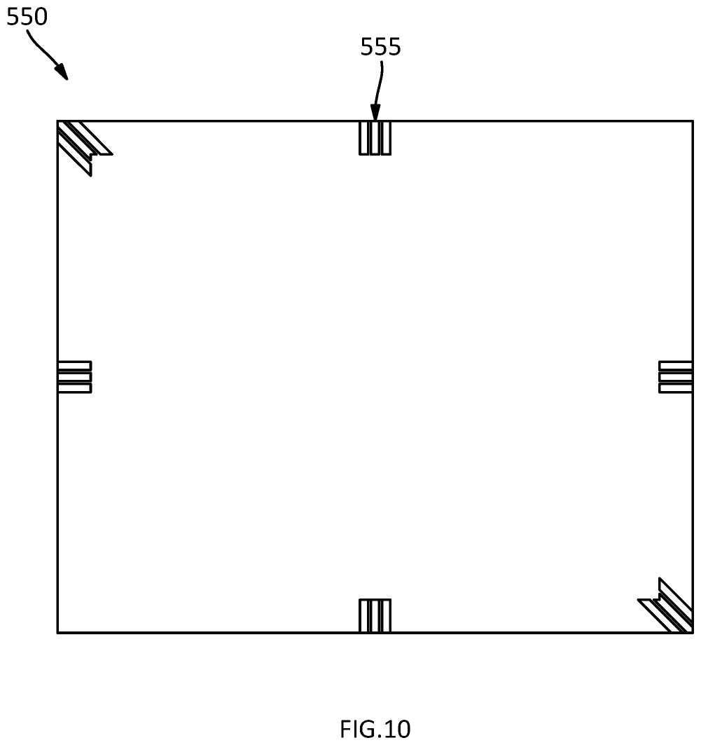

FIG. 9A shows a plan view of an example electronic device, FIG. 9B shows a cross-sectional view taken along the line D-D of FIG. 6A, and FIG. 9C shows a cross-sectional view taken along the line E-E of FIG. 6A. FIG. 10 shows a bottom view illustrating a lid shown in FIG. 9A. In the example shown in FIGS. 9A to 9C, electronic device 500 can comprise cavity substrate 410, electronic component 120, adhesive 140, lid 550, external interconnects 160, venting channels 115A and 555, and vent seal 173. In some examples, lid 550 can comprise corresponding elements, features, materials, or formation processes similar to those of lid 450 or other lids described here. Lid 550 does not need to comprise trench layer 451 of FIG. 6A.

Lid 550 can comprise venting channels 555. In some examples, venting channel 555 can comprise corresponding elements, features, materials, or formation processes similar to those of venting channels described here, such as venting channel 455. Referring to FIGS. 9A to 9C and FIG. 10, venting channels 555 can be at a bottom side of lid 550. In some examples, the bottom side of lid 550 can be referred to as a trench side. Venting channels 555 can comprise or be referred to as lateral venting channels. Venting channels 555 can be trenches or grooves penetrating from the bottom side and towards the top side of lid 550. Venting channels 555 can be trenches or grooves extending laterally towards a lateral side of lid 550. Venting channels 555 can be located to align with wall steps 4122 of cavity wall 412 where venting channels 555 can be in lid 550 over one or more wall steps 4122. Portions of venting channels 555 can extend over wall steps 4122 and into the interior of cavity 113. In some examples, when there is a pressure imbalance between the interior and exterior of cavity 113, the compressed air or gas in cavity 113 can be vented or leaked through venting channels 555 over wall steps 4122.

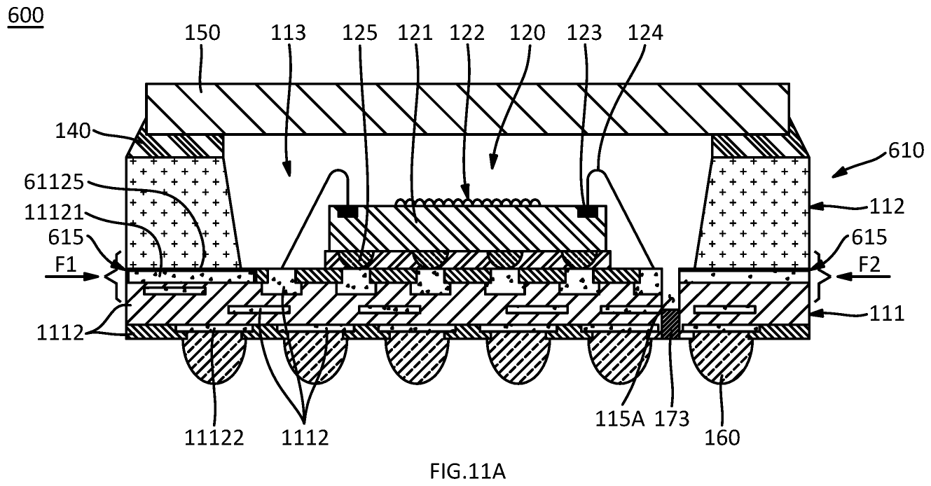

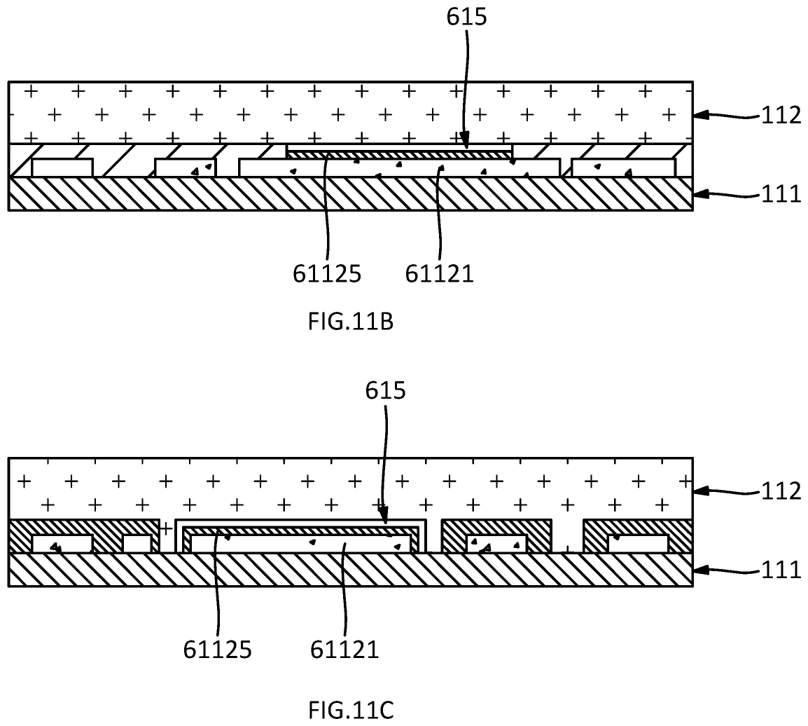

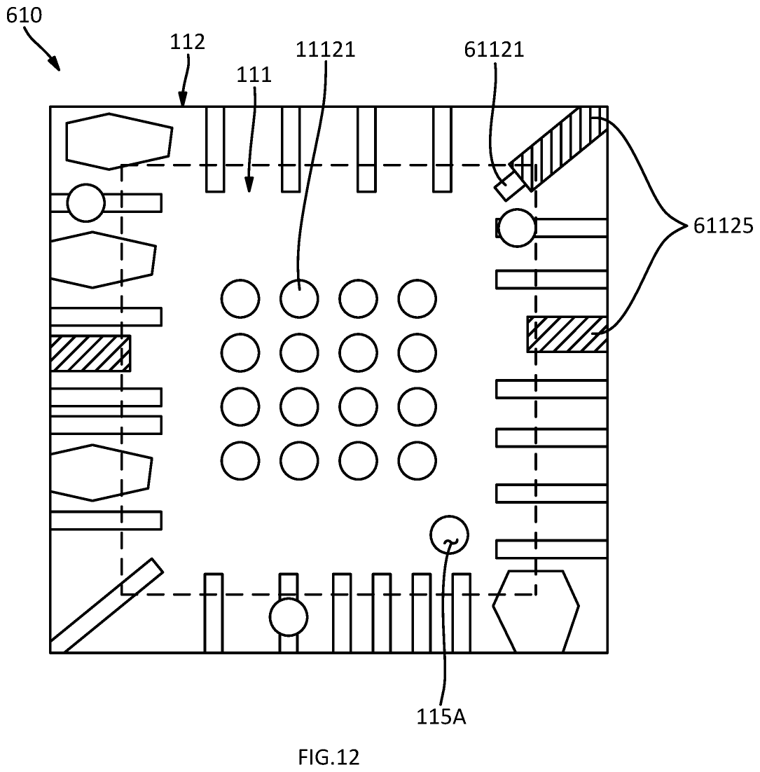

FIG. 11A shows a cross-sectional view of an example electronic device 600, FIG. 11B shows a side view of electronic device 600 taken in a direction F1 of FIG. 1A, and FIG. 11C shows a side view of electronic device 600 taken in a direction F2 of FIG. 1A. FIG. 12 shows a plan view of substrate 610 shown in FIG. 11A. In the example shown in FIGS. 11A to 11C, electronic device 600 can comprise cavity substrate 610, electronic component 120, underfill 130, adhesive 140, lid 150, external interconnects 160, venting channels 115A and 615, and vent seal 173. In some examples, cavity substrate 610 can comprise corresponding elements, features, materials, or formation processes similar to those of cavity substrate 110 previously described. Cavity substrate 610 can comprise conductive tracks 61121 and gate coatings 61125.

Conductive tracks 61121 can comprise or be referred to as conductive traces or conductive patterns. Conductive tracks 61121 can be part of conductive structure 1112. In some examples conductive tracks 61121 can comprise part of, or one or more of, inward terminals 11121. Conductive tracks 61121 can extend under cavity wall 112 and laterally from the periphery of substrate base 111 to cavity 113. Conductive tracks 61121 can be exposed at the first side of substrate base 111. Conductive tracks 61121 can be partially covered by cavity wall 112. In some examples, conductive tracks 61121 can comprise an electrically conductive material, such as copper, aluminum, palladium, titanium, tungsten, titanium/tungsten, nickel, gold, or silver. Conductive tracks 61121 can be formed using, for example, sputtering, electroless plating, electroplating, physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD).

Gate coatings 61125 can be provided on one or more conductive tracks 61121. For example, gate coatings 61125 can be provided on top sides or lateral sides of conductive tracks 61121. Gate coatings 61125 can comprise or be referred to as plating layers or cover layers.

Referring to FIG. 12, gate coatings 61125 can entirely or partially cover conductive tracks 61121. Gate coatings 61125 can cover portions of conductive tracks 61121 positioned under cavity wall 112. In some examples, gate coatings 61125 can comprise plated Au, solder, or Cu organic solderability preservative (OSP). Gate coatings 61125 can comprise a material having low adhesiveness to the material of cavity wall 112. For example, the adhesiveness of gate coating 61125 to the material of cavity wall 112 can be lower than the adhesiveness of conductive tracks 61121 to the material of cavity wall 112. Referring to FIGS. 11B and 11C, sufficient pressure imbalance between the interior and exterior of cavity 113 can form venting channels 615 by overcoming the adhesion between gate coatings 61125 and cavity wall 112, so that the compressed air or gas in cavity 113 can be vented or leaked through venting channels 615.

Venting channels 615 can comprise or be referred to as lateral venting channels, ventilation gates, micro gaps, or delamination channels. Venting channels 615 cam be located between gate coatings 61125 and cavity wall 112. Referring to FIG. 11B, venting channels 615 can be formed between top portions of gate coatings 61125 and cavity wall 112. Referring to FIG. 11C, venting channels 615 can be formed between top portions of gate coatings 61125 and cavity wall 112, and between side portions of gate coatings 61125 and cavity wall 112. In some examples, venting channels 615 can be provided as channels for venting or leaking the compressed air in cavity 113 in the lateral (or horizontal) direction.

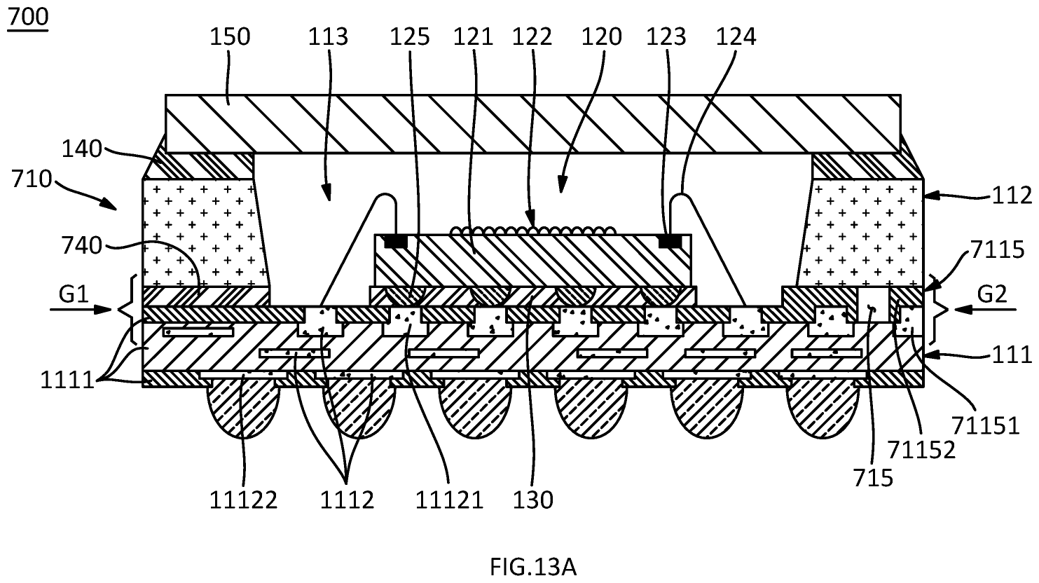

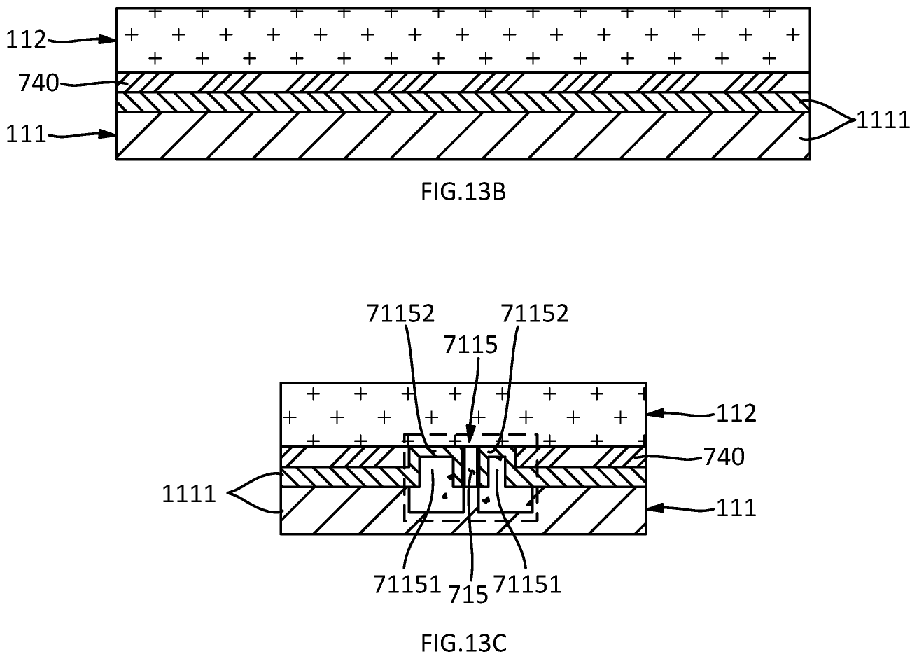

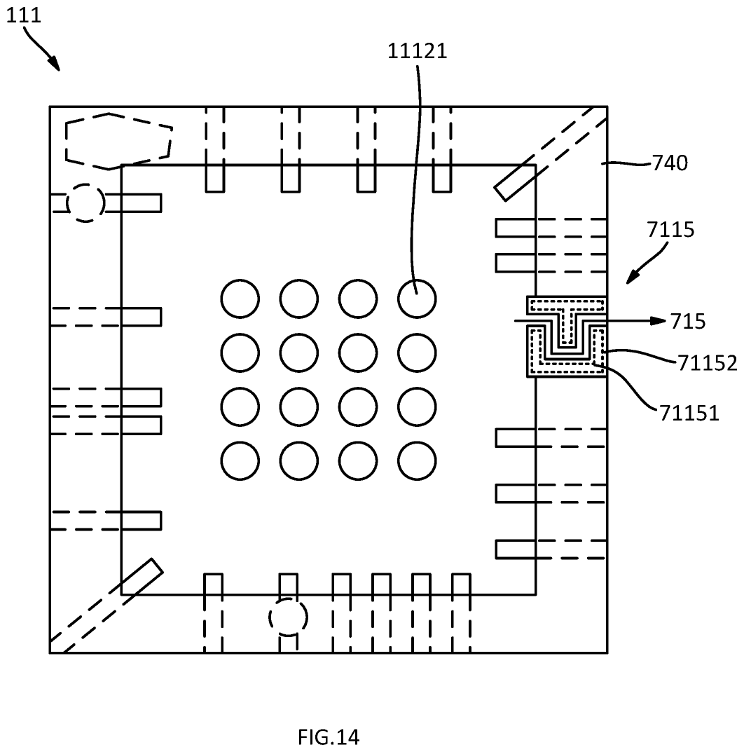

FIG. 13A shows a cross-sectional view of an example electronic device 700, FIG. 13B shows a side view of electronic device 700 taken in a direction G1 of FIG. 13A, and FIG. 13C shows a side view of electronic device 700 taken in a direction G2 of FIG. 13A. FIG. 14 shows a plan view of substrate 710 shown in FIG. 13A. In the example shown in FIGS. 13A to 13C, electronic device 700 can comprise cavity substrate 710, electronic component 120, underfill 130, adhesives 140 and 740, lid 150, external interconnects 160, and venting channel 715. In some examples, cavity substrate 710 can comprise corresponding elements, features, materials, or formation processes similar to those other cavity substrates described here, such as cavity substrate 110. Cavity substrate 710 can comprise vent structure 7115.

In some examples, adhesive 740 can be provided between substrate base 111 and cavity wall 112. Adhesive 740 can attach cavity wall 112 to substrate base 111. Referring to FIG. 14, adhesive 740 can be located at portions on substrate base 111 aligned with cavity wall 112, for example at a periphery of substrate base 111, but excluding the area over vent structure 7115 of substrate base 111. Adhesive 740 can expose vent structure 7115. In some examples, adhesive 740 can comprise corresponding elements, features, materials, or formation processes similar to those of adhesive 140 previously described.

Vent structure 7115 can comprise or be referred to as a vent dam. In some examples, vent structure 7115 can prevent adhesive 740 from entering venting channel 715. Vent structure 7115 can be part of substrate base 111. Vent structure 7115 can protrude from the first side of substrate base 111. A top side of vent structure 7115 can be coplanar with a top side of adhesive 740. Vent structure 7115 can contact cavity wall 112. Vent structure 7115 can be partially covered by cavity wall 112. Vent structure 7115 can extend to the interior of cavity 113 further than adjacent cavity wall 112. Vent structure 7115 can define venting channels 715. Vent structure 7115 can vent or leak air or gas. Vent structure 7115 can block leakage of light. Vent structure 7115 can comprise cs 71151 and vent seal 71152.

Vent tracks 71151 can comprise or be referred to as conductive traces, conductive patterns, channel patterns, or colon patterns. Vent tracks 71151 can be part of conductive structure 1112. In some examples, vent tracks 71151 can be coupled to or be part of inward terminals 11121. In some examples, vent tracks 71151 can be dummy or electrically isolated conductive patterns decoupled from inward terminals 11121 or outward terminals 11122. In some examples, vent tracks 71151 can be arranged outside inward terminals 11121. In some examples, vent tracks 71151 can extend under cavity wall 112 to the interior of cavity 113. Vent tracks 71151 can comprise two tracks spaced apart from each other, defining venting channel 715 in between. In some examples, vent tracks 71151 can comprise spaced apart conductive traces contacting substrate base 111. Venting channels 715 can be formed by spaced-apart vent tracks 71151. Referring to FIG. 14, vent tracks 71151 can be arranged on substrate base 111 so as to define the pathway of venting channels 715 with one or more bends. Some of spaced-apart vent tracks 71151 overlap each other, thereby preventing light leakage. In some examples, vent tracks 71151 can comprise an electrically conductive material, such as copper, aluminum, palladium, titanium, tungsten, titanium/tungsten, nickel, gold, or silver. Vent tracks 71151 can be formed using, for example, sputtering, electroless plating, electroplating, physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD).

Vent seal 71152 can cover lateral or top sides of vent tracks 71151. Vent seal 71152 can be part of dielectric structure 1111. Vent seal 71152 can contact cavity wall 112. In some examples, vent seal 71152 can cover top portions of vent tracks 71151 and a lower portion of cavity wall 112. In some examples, vent seal 71152 can comprise an electrically insulating material, such as a dielectric material, a solder resist, a polymer, polyimide (PI), benzocyclobutene (BCB), polybenzoxazole (PBO), bismaleimide triazine (BT), a molding material, phenol resin, epoxy, silicone, or acrylate polymer. In some examples, vent seal 71152 can be formed using a process, such as spin coating, spray coating, printing, oxidation, physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD).

Venting channel 715 can be provided between the interior and exterior of cavity 113 through vent structure 7115. The path of venting channel 715 can be established by vent tracks 71151. Venting channel 715 can comprise or be referred to as a lateral venting channel. Venting channel 715 can be positioned between substrate base 111 and cavity wall 112. Venting channel 715 can be a channel for connecting cavity 113 with an external environment. In some examples, venting channel 715 can be provided as a channel for venting or leaking the compressed air or gas in cavity 113 in the lateral or horizontal direction. In some examples, when there is a pressure imbalance between the interior and exterior of cavity 113, the compressed air or gas in cavity 113 can be vented or leaked through venting channel 715.

The present disclosure includes reference to certain examples, however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

1. An electronic device, comprising:
a cavity substrate comprising:
a substrate base comprising a top side and a bottom side; and
a cavity wall over the substrate base and defining a cavity;
an electronic component over the substrate base and in the cavity;
a lid comprising a top side and a bottom side, wherein the lid is over the substrate base and the cavity wall to define an interior of the cavity and an exterior of the cavity;
an adhesive between the bottom side of the lid and a top side of the cavity wall; and
a vent seal between the interior of the cavity and the exterior of the cavity.

2. The electronic device of claim 1, wherein the vent seal contacts the adhesive and the top side of the cavity wall.

3. The electronic device of claim 1, wherein the vent seal contacts the bottom side of the lid and the top side of the cavity wall.

4. The electronic device of claim 1, comprising a venting channel defined in the lid, the venting channel extends from the top side of the lid to the bottom side of the lid.

5. The electronic device claim 4, wherein the vent seal is in the venting channel.

6. The electronic device of claim 4, wherein the vent seal contacts the top side of the lid and is exterior to the cavity.

7. The electronic device of claim 4, wherein the venting seal contacts the bottom side of the lid and is interior to the cavity.

8. The electronic device of claim 1, further comprising a venting channel defined in the substrate base, wherein the venting channel extends from the top side of the substrate base to the bottom side of the substrate base.

9. The electronic device of claim 8, wherein the vent seal is in the venting channel.

10. The electronic device of claim 8, wherein the vent seal contacts the top side of the substrate base and is interior to the cavity.

11. The electronic device of claim 8, wherein the vent seal contacts the bottom side of the substrate base and is exterior to the cavity.

12. The electronic device of claim 1, wherein the vent seal is permeable and comprises a carrier film that is impermeable.

13. An electronic device, comprising:
a cavity substrate comprising:
a substrate base comprising a top side and a bottom side; and
a cavity wall over the substrate base and defining a cavity;
an electronic component over the substrate base and in the cavity;
a lid comprising a top side and a bottom side, wherein the lid is over the substrate base and the cavity wall to define an interior of the cavity and an exterior of the cavity;
an adhesive between a bottom side of the lid and a top side of the cavity wall; and
a venting channel between the interior of the cavity and the exterior of the cavity.

14. The electronic device of claim 13, further comprising a trench layer contacting the bottom side of the lid, wherein the trench layer is adjacent the top side of the cavity wall, and the venting channel is in the trench layer.

15. The electronic device of claim 14, wherein the adhesive contacts a bottom of the trench layer.

16. The electronic device of claim 13, wherein the cavity wall comprises a wall step, and the venting channel is in the lid and over the wall step.

17. The electronic device of claim 13, wherein the cavity substrate comprises vent tracks comprising spaced apart conductive traces contacting the substrate base, wherein the venting channel is defined by the vent tracks.

18. A method to manufacture an electronic device, comprising:
providing a cavity substrate comprising a substrate base having a top side and a bottom side, and a cavity wall over the substrate base and defining a cavity;
providing an electronic component over the substrate base and in the cavity;
providing a lid comprising a top side and a bottom side, wherein the lid is over the substrate base and the cavity wall to define an interior of the cavity and an exterior of the cavity;
providing an adhesive between a bottom side of the lid and a top side of the cavity wall; and
providing a vent between the interior of the cavity and the exterior of the cavity.

19. The method of claim 18, wherein the vent comprises a vent seal, wherein the vent seal is between the interior of the cavity and the exterior of the cavity.

20. The method of claim 18, wherein the vent comprises a venting channel extending laterally at a bottom of the lid.
